(19) United States
(12) Patent Application Publication
(10) Pub. No.: US 2014/0145309 A1
(43) Pub. Date: May 29, 2014

(54) Systems For The Recycling of Wire-Saw Cutting Fluid

(71) Applicant: MEMC SINGAPORE, PTE. LTD (UEN200614797D), (US)

(72) Inventors: Alexis Grabbe, St. Charles, MO (US); Sasha Joseph Kweskin, St. Louis, MO (US); Larry Wayne Shive, St. Charles, MO (US); Henry Frank Erk, St. Louis, MO (US)

(73) Assignee: MEMC SINGAPORE, PTE. LTD (UEN200614797D), Singapore (SG)

(21) Appl. No.: 13/684,812

(22) Filed: Nov. 26, 2012

(51) Int. Cl. F28F 19/01; H01L 29/34

(52) U.S. Cl. CPC F28F 19/01; H01L 29/34
USPC 257/618; 210/195.1

(57) ABSTRACT

A process is provided for treating coolant fluid used in wire-saw cutting of semiconductor wafers and which contains silicon-containing impurities. The process comprises changing the properties of the used coolant fluid so that the silicon-containing impurities may be filtered and separated from the coolant fluid to thereby yield a coolant fluid filtrate suitable for use in a wire-saw cutting operation.

### FIELD OF THE INVENTION

The field of the invention relates generally to a method for treating coolant fluid used in wire-saw cutting of semiconductor wafers, and more particularly to a method for reducing the total concentration of silicon-containing impurities in used coolant fluid, and even more particularly to reducing the content of insoluble silicon-containing impurities in the used coolant fluid.

### BACKGROUND OF THE INVENTION

The surface quality of semiconductor wafer (e.g., silicon wafer) sawed by diamond wire-sawing is important in the semiconductor and photovoltaic industries. In general, semiconductor wafers prepared by wire-sawing have typical defects that may be affected by the quality of the coolant used in the wire-saw process. The coolant itself is water based and has additives which are non-ionic polymeric surfactants (such as PEG, PEO, PPO, or Pluronic PEO/PPO block copolymers), pH buffers, anticorrosion agents, and may contain anti-foaming agents. The additive mixture may be any known coolant composition in the art.

Without special treatment, coolant fluid accumulates impurities during wire-saw cutting, specifically silicon-containing impurities, such as silicates and silicon swarf particles. The silicon/silicate content as solids may increase to 1000 ppm or higher. The increase in silicon-containing impurities detrimentally affects the wire-saw cutting operation and filter rates during coolant recycling, which may cause defects on the surface of the sliced semiconductor wafer. In some instances, it has been observed that wires can be deflected so far from their guide positions as to touch each other, called doubling, which impairs the cutting operation's ability to cut wafers of uniform thickness. The defects that have been observed on the surfaces of sliced semiconductor wafers include:

(1) Irregularly-patterned surface staining (flower stains);

(2) Post Cut Clean-ability and irregular oxidation and etching;

(3) Total thickness variations.

The detrimental effects of slow coolant fluid filtering, thereby affecting throughput, and defects on the surfaces of the as-cut wafers are both linked by the silicon/silicate particles that buildup during a wire-saw cutting process. A process is needed therefore that removes the silicon-containing swarf without unduly altering the properties of the coolant fluid. Stated another way, a process is needed for recycling used coolant fluid from a wire-saw cutting operation that substantially returns the coolant fluid to the cooling properties of fresh coolant fluid solution.

### BRIEF DESCRIPTION OF THE INVENTION

The present invention is directed to a process for treating coolant fluid used in wire-saw cutting of semiconductor wafers, the coolant fluid containing silicon-containing impurities. The process comprises contacting the coolant fluid with a flocculant polymer to thereby form aggregate particles comprising the silicon-containing impurities and the flocculant polymer and filtering the coolant fluid comprising the aggregate particles to separate the aggregate particles from the coolant fluid to thereby yield a coolant fluid filtrate.

The present invention is further directed to a process for treating used coolant fluid after a wire-saw cutting operation of semiconductor wafers, the used coolant fluid containing silicon-containing impurities and having a first pH. The process comprises contacting the used coolant fluid with an acid to thereby lower the pH of the used coolant fluid to a second pH sufficient to precipitate the silicon-containing impurities; filtering to used coolant fluid to separate the precipitated silicon-containing impurities from the coolant fluid to thereby yield a coolant fluid filtrate; and contacting the coolant fluid filtrate with a base to thereby raise the pH of the coolant fluid filtrate to a third pH to thereby yield a treated coolant fluid. The contact of the coolant fluid filtrate with the base further precipitates a salt comprising an anion from the acid and a cation from the base.

The present invention is still further directed to process for treating used coolant fluid after a wire-saw cutting operation of semiconductor wafers, the used coolant fluid containing silicon-containing impurities and having a first pH. The process comprises contacting the used coolant fluid with an acid to thereby lower the pH of the used coolant fluid to a second pH sufficient to precipitate the silicon-containing impurities; filtering to used coolant fluid to separate the precipitated silicon-containing impurities from the coolant fluid to thereby yield a coolant fluid filtrate; and contacting the coolant fluid filtrate with an organic base to thereby raise the pH of the coolant fluid filtrate to a third pH to thereby yield a treated coolant fluid.

The process is still further directed to an as-cut silicon wafer having a central axis, a front surface and a back surface that are generally perpendicular to the central axis, a central plane in a bulk region of the structure between and parallel to the front and back surfaces, a circumferential edge, wherein the front surface, the back surface or both the front surface and the back surface of the as-cut silicon wafer has less than 2·10⁻⁴ gm/cm² silicon-containing impurities, the concentration of silicon-containing impurities is invariant with respect to the age of the coolant fluid used in the cutting operation, and the coolant fluid has been recycled from at least one prior wire-saw cutting operation.

The process is still further directed to a temperature-controlled circulatory system for conveying coolant fluid for use in wire-saw cutting of semiconductor wafers. The circulatory system comprises a reaction/aging tank, wherein used coolant fluid is contacted with a flocculant polymer to thereby form aggregate particles comprising the silicon-containing swarf and the flocculant polymer; a filter system comprising a filter for separating the aggregate particles from the coolant fluid, to thereby yield a coolant fluid filtrate; and a wire-saw cutting apparatus.

### BRIEF DESCRIPTION OF THE DRAWINGS

FIG. 1 is a schematic of the cutting process.

FIGS. 2A and 2B are graphs depicting number weighted (FIG. 2A) and intensity-weighted (FIG. 2B) dynamic light scattering data of impurities present in used coolant fluid filtered to using a 20 nm filter.

FIG. 3 is a schematic of the sawing process looking down the axis of the wires. The cutting area is at the top of the image and used coolant drips downward. Clouding should be confined to the cutting zone.

FIGS. 4A and 4B are images of swarf particles. FIG. 4A is a scaled photograph of swarf particles, and FIG. 4B depicts an overlay of swarf particles on used wire with diamonds.

FIG. 5 are images of wafers showing aggregation patterns on wafers before cleaning which lead to permanent stains after cleaning.

FIG. 6 is an SEM image depicting the resulting stains after cleaning, which appear to be nothing more than etch masking.

FIG. 7A depicts a collapsed cake schematic depicting a state associated by poor filtration.

FIG. 7B is an SEM image of an aggregate.

FIG. 8 is a depiction of efficient flow through a cake of floc particles, which is faster than through a collapsed cake of swarf particles. With sticky particles, floc aggregates form and retain open channels.

FIG. 9 is a schematic of a bipolar electrodialysis system (“BPED”).

FIG. 10 is a schematic of a coolant recovery and recycling system, showing only material paths, no pumps, valves, or controls are shown. Concentrations are controlled by a feed-back system.

FIG. 11 is a graph depicting wafer cleanliness data for successive filtration cycles using Polyacrylamide flocculant Tramfloc 302.

FIG. 12 is a graph depicting loading and resultant flow rate of a Polyacrylamide treated used coolant in a cake filter system.

FIG. 13 is a graph depicting the filtration of swarf dosed with polyoxetonium chloride (“PQ”) over a series of trials to recover and reuse coolant for diamond wire slicing of silicon.

FIG. 14 is a graph depicting the buildup of chloride in a coolant recovery system as measured by test strips with different bleed/feed rates for coolant. The detection limit by this method is about 50 ppm chloride.

FIG. 15 is a graph showing total silicates in PQ treated and filtered coolant measured as total silicon. pH is held at 9.5.

FIG. 16 is a graph depicting the change in pH of the coolant fluid using the weak base, PEI, as a flocculating agent. The swarf pH without PEI addition is about 9.4-9.5. At 15 ppm the pH shift is negligible.

FIG. 17 is graph depicting filtration of swarf dosed with PEI over a series of trials to recover and reuse coolant for diamond wire slicing of silicon. The oddly marked flow rate data point is discussed in the text.

FIG. 18 is a graph depicting dosing and average filtration rate. Poor coolant quality was related to an instance of AMP pH adjustment.

FIG. 19 is a graph depicting the trend of cleanliness level of wafers treated with coolant recycled with filtration assisted with PEI, as-cut, and after a simple clean.

FIG. 20 is a calibration curve of turbidity v. swarf concentration measured for a series of solutions.

FIG. 21 is a graph of flow rate v. time for coolant fluids treated with PEI and PQ42.

FIG. 22 is a graph of pressure v. time for coolant fluids treated with PEI and PQ.

### DETAILED DESCRIPTION OF THE INVENTION

The present invention is directed to a method for improving the properties of diamond wire-saw coolant fluid for both efficient filtration during coolant recycling and for efficient cutting of semiconductor wafer. Stated another way, the properties of a coolant fluid used in the wire-saw cutting of semiconductor wafers may be toggled between properties optimized for filtration during a recycling process and properties optimized for cutting wafers during a wire-saw cutting process. In a diamond wire-saw cutting process, used coolant fluid accumulates impurities, particularly, silicon-containing impurities, such as silicates and silicon swarf particles, and chemical by-products, such as impurities arising from contamination of the coolant including particles arising from cutting of the epoxy and beam. According to the method of the present invention, used coolant fluid is recycled by contacting the used coolant fluid with a flocculant which effectively flocculates silicon-containing impurities, followed by filtration to remove the flocculated silicon-containing impurities. During the coolant fluid recycling process, used coolant fluid is contacted with a flocculant, which causes silicon particles and the flocculant to agglomerate into particles of sufficient size to enable removal thereof by filtration. Such flocculation followed by filtration reduces the content of silicon-containing impurities, such as silicates and silicon swarf, to the normal solubility limit. Advantageously, the flocculant material does not substantially break through the filter and thus does not pass through the filtration step and into the wire-saw cutting operation. The method of the present invention thus effectively removes silicon-containing impurities from used coolant fluid while additionally returning the properties of the used coolant fluid filtrate to substantially that of fresh coolant fluid. The present invention enables recycling of coolant fluid so that it is suitable for use in multiple wire-saw cutting operations. The method of the present invention therefore enables recycling of coolant fluid through at least 15 cycles, wherein each cycle comprises use in a cutting operation, flocculation and aging, filtration, and return to the cutting operation. Advantageously, the recycled coolant fluid may be used through at least 20 such cycles, at least 30 cycles, or even at least 50 cycles. In some embodiments, the recycled coolant fluid may be used through at least 50 to 150 cycles, with a feed rate to replenish fluid lost with the discarded rate generally in the range of between 1% and 10%, preferably between about 3% and about 5%. In some embodiments, the method of the present invention enables recycling through an indefinite number of cycles along with a bleed and feed rate between about 3% and about 5%. Makeup fluid may be added during each cycle. The method of the present invention enables recycling of coolant fluid through multiple wire-saw cutting operations without the need for wholesale replacement of the coolant fluid after only a few cycles. It was observed, prior to implementing the process of the present invention, that the coolant fluid was generally dark amber due to a high content of silicon particles after about 20 cycles, after which point the entirety of the coolant fluid was discarded. Accordingly, the method of the present invention enables the recycling of coolant fluid through a substantially larger number of cycles prior to replacement of the entire fluid.

In some embodiments, the present invention is directed to a wire-saw cutting process for cutting semiconductor wafers from a semiconductor ingot or ingot segment, which comprises the step of recycling the coolant fluid. Coolant fluid recycling comprises the steps of flocculation, followed by filtration. The semiconductor ingot or segments thereof comprise a material selected from the group consisting of silicon, silicon carbide, silicon germanium, silicon nitride, silicon dioxide, and combinations thereof. In addition, the system can be extended to other materials at appropriate material-specific pH and flocculating agent, provided that the flocculating agent remains strongly bound to the surface of the particles in the used coolant fluid. In some embodiments, the semiconductor ingot segments are sliced from a single crystal silicon ingot grown in accordance with conventional Czochralski crystal growing methods. Such methods, as well as standard silicon slicing, lapping, etching, and polishing techniques are disclosed, for example, in F. Shimura, Semiconductor Silicon Crystal Technology, Academic Press, 1989, and Silicon Chemical Etching, (J. Grabmaier Ed.) Springer-Verlag, N.Y., 1982 (incorporated herein by reference). In some embodiments, the semiconductor ingot segments are sliced from polycrystalline silicon ingots, such as those prepared by, e.g., directional solidification.

The slicing operation is typically performed by an inner diameter slicing apparatus or by a wire-saw slicing apparatus. The basic principle of wire-sawing is to feed the ingot into a web of ultra-thin, fast moving wire. The cutting action of the wire is actually created by fixed abrasive in the wire as the wire is transported in a rapid, back and forth lateral motion. The wire web is in effect, a single wire being fed from one large spool to another. Depending on the wire diameter, each spool can hold hundreds of kilometers of wire on it. The wire-saw technology allows for the entire ingot to be sliced simultaneously, thus, lowering cycle time while minimizing “kerf” loss.

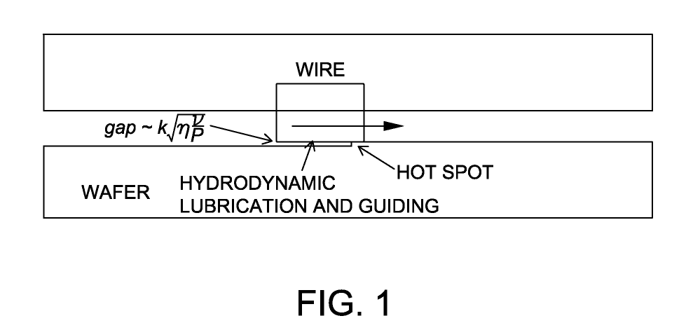

FIG. 1 is a schematic of the wire-saw cutting process of a semiconductor ingot. The equation for hydrodynamic gap is roughly approximate. Herein, the sliding velocity is ν, the local viscosity is η, P is the local hydrodynamic pressure, and k is a constant. It is currently believe that heat generation at the cutting edge causes coolant to cloud and convert from single phase to dual phase (a polymer-rich phase and a polymer poor phase) allowing:

(1) lubrication by the polymer rich phase to partly hydrodynamic if temperature gets too high, caused by a jump in viscosity η immediately underneath the Diamond and just behind the cut,

(2) cooling by the polymer-poor phase,

(3) cutting without excess local forces leading to wire break.

In a conventional wire-saw cutting process, the coolant fluid builds up silicon-containing impurities, which include silicon and oxidized silicon in the form of silicates or silicon containing swarf particles. Oxidized silicate impurities include SiO₂, Si(OH)₄, SiO₃(OH), SiO₂(OH)₂, and polymeric oxidized silicates. The coolant fluid may become contaminated with other impurities from sliced glue and beam materials. Still other impurities may result from the breakdown of coolant additives. It has been observed that a single cutting operation may contaminate the coolant fluid with silicon containing impurities up to 200 ppm, or even up to 1000 ppm (kg/liter Si) or higher.

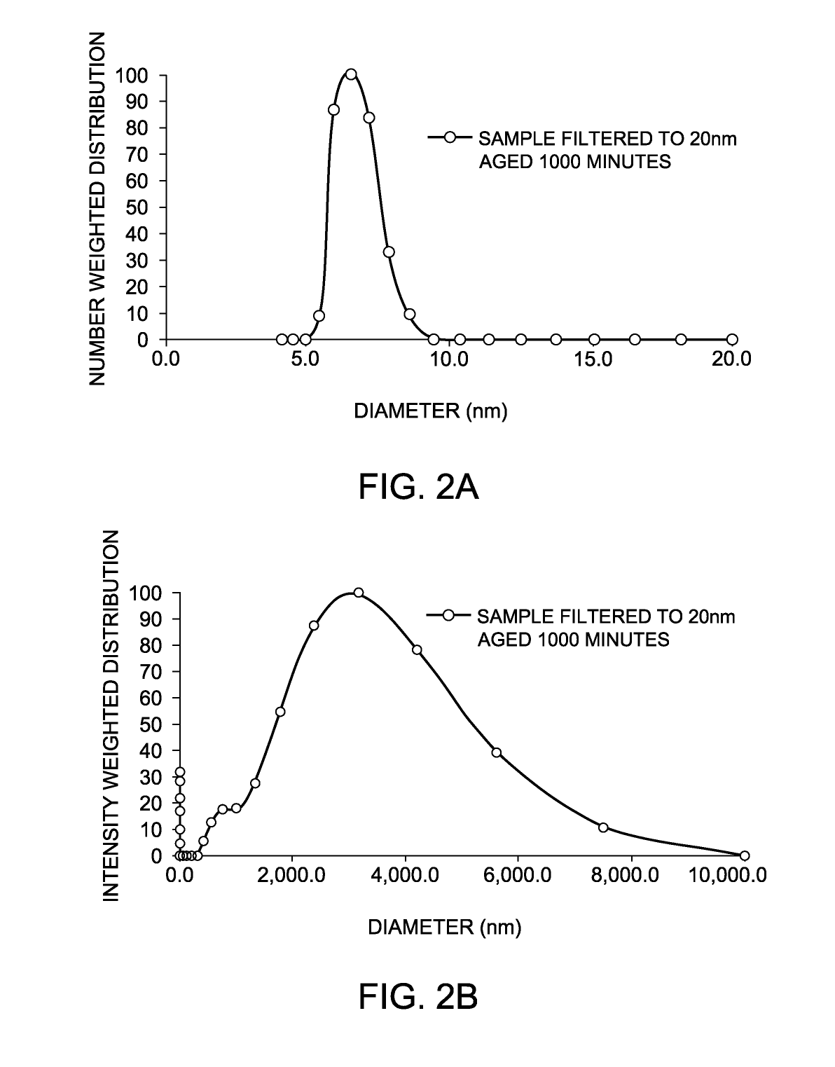

A conventional method of recycling used coolant fluid to remove silicon-containing impurity particles involves filtering through a 20 nm filter. Empirical results to date indicate that a sample filtered through a 20 nm filter contains a substantial quantity of silicon containing particles having diameters smaller than 20 nm. See FIGS. 2A and 2B, which are graphs depicting number weighted (FIG. 2A) and intensity weighted (FIG. 2B) dynamic light scattering data of impurities present in used coolant fluid filtered using a 20 nm filter. The data are histograms with curves added to guide the eye. FIG. 2A depicts the silica particles having diameters smaller than 20 nm present in filtrate. Accordingly, small colloidal particles are present in the recycled coolant. Cutting and filtering at high pH does not allow the smaller silica or silicon particles to filter out.

As is apparent from FIG. 2B, weighting the data by light scattering intensity reveals apparently large size particles in the coolant fluid filtrate, whether the sample is aged or not. These particles having particle sizes substantially greater than the 20 nm filter. It was discovered that the large size particle signal is not derived from solid particles, but rather from aggregates of polymers in the coolant fluid filtrate. The structures are much larger than individual polymer molecules, and these extended structures lend to coolant fluid its desirable viscous properties in cutting.

It is currently believed that excess particles, e.g., silicon containing particles in the coolant interfere with the cutting at the contact point by interposition leading to reduced cutting efficiency, resulting in increased wire usage, and an increase in the gap preventing hydrodynamic stabilization of wire in the cutting channel, resulting in wire drift and increased total thickness variation in the finished wafers. It is desirable that any coolant delivered to the cutting zone be as free of particles as possible. Regardless of the reason, it has been observed empirically that wire-saw performance declines with increasing solids content measured as total silicon (including colloidal SiO₂) along with Si kerf particles. The decline in wire-saw performance has required wholesale disposal of the coolant fluid after, generally, at most 10 to 20 cutting operations, depending on the length of the wire used per cut.

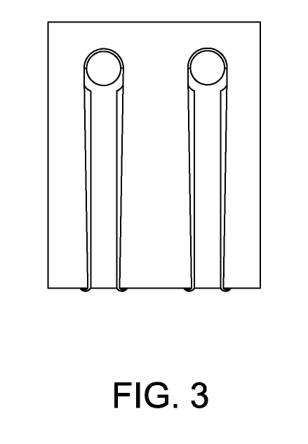

During a wire-saw cutting operation, different cutting zones require different action of the coolant during slicing. FIG. 3 is a schematic of the sawing process looking down the axis of the wires. Above the wires is the cutting area. At either side of the wire and along the length of the cut, used coolant drips downward. Clouding, a symptom of coolant polymer aggregation, is ideally confined to the cutting zone.

Drainage of surfactant along the length of the cut between the wafers, Marangoni flow, and masking by swarf particles causes the wafer surface to irregularly oxidize and etch in subsequent processes. The result is staining, particularly during the post-cut cleaning process. Certain antifoam agents can exaggerate staining. Additionally, excess forces between wafers due to surface tension can lead to demount (fallen wafers). Excessive surface tension can draw wires together leading to poor total thickness variation.

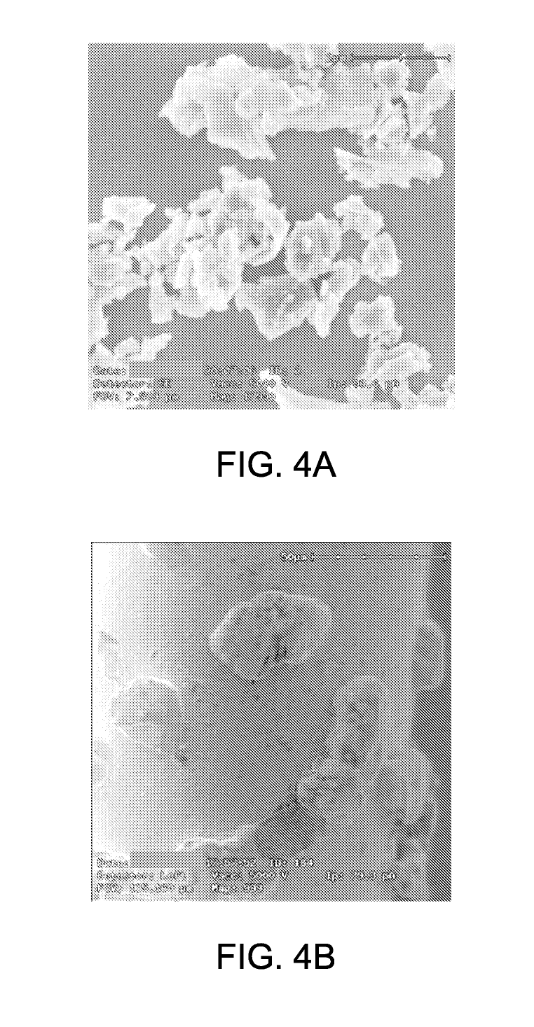

During a wire-saw cutting operation, the following properties are desired: (1) repulsive forces between particle-particle and particle-wire; (2) uniform low surface tension; (3) passivation against differential etching; (4) temperature below the cloud point away from the wire; and (5) weak lateral tension between wires. It is crucial that that conditions in sawing forbid hard attachment to wire or wafer, by an oxide bridge. Unfortunately, the swarf particle shape allows a lot of adhesion, which is undesirable in the cutting operation wherein repulsive forces are desired. FIG. 4A depicts individual swarf particles, while FIG. 4B depicts the diamond impregnated wire at a larger scale, where patches of swarf aggregates can just be seen. These high aspect ratio particles, not in the fully colloidal regime, if not hard attached to a surface should be sheared off in cleaning.

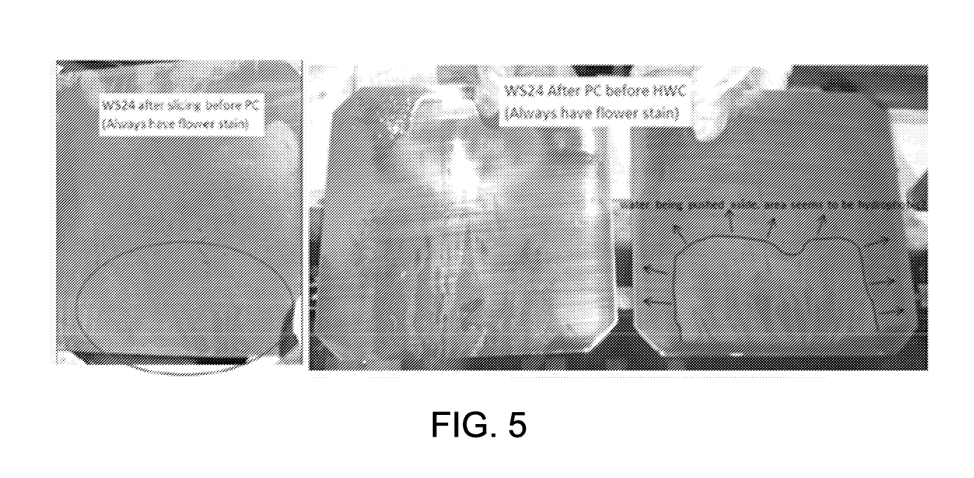

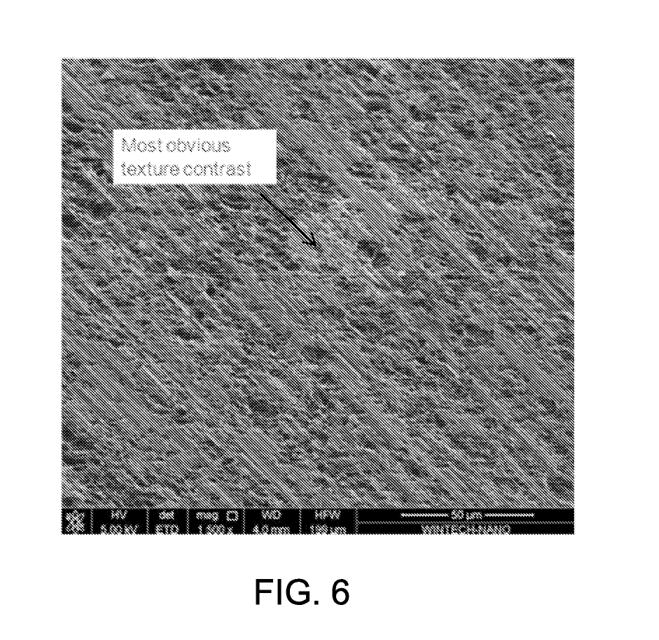

FIG. 5 includes photographs of as-cut wafers depicting aggregation patterns before cleaning. These aggregation patterns may lead to permanent stains after cleaning. These aggregation patterns are enhanced by hydrophobic absorption of silicon-containing anti-foam impurities. FIG. 6 is photograph of the resulting stains after cleaning, which are a change in texture rather than a surface contaminant.

Additionally, the silicon-containing swarf materials can adsorb antifoam agents and become locally hydrophobic particles which will tend to bunch together. However, anytime attractive forces are present the particles will tend to segregate on the wafer surface. This will lead to differential etching and patterns on the wafer surface. Therefore, for the purposes of cutting (to prevent choking of the cutting channel) and cleaning (to prevent staining) the coolant composition should be designed to so that the dominant inter-particle and particle-wafer forces are repulsive. However, the exact opposite behavior is advantageous for filtration.

A coolant fluid that has been used in a wire-saw cutting operation may become loaded with particles of the type seen in FIGS. 4A and 4B, at a level of approximately 1 to 20 grams solids per liter. The act of filtration involves the build-up of thin cake over the filter media pores, followed by deposition of a thick cake. Typically the pore size of the filter media is larger than the main distribution of particles, and thin cake formation depends on the bridges developed by a small population of large particles.

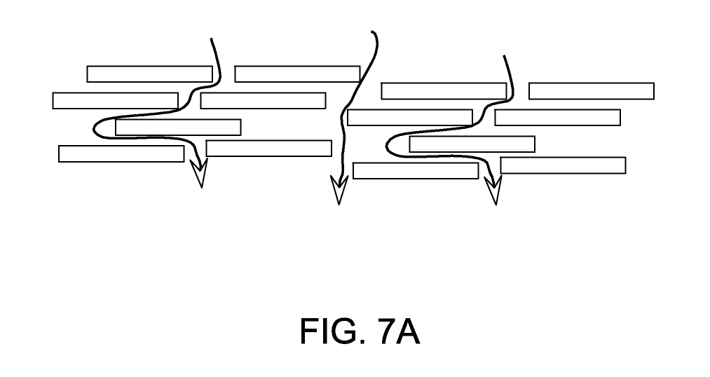

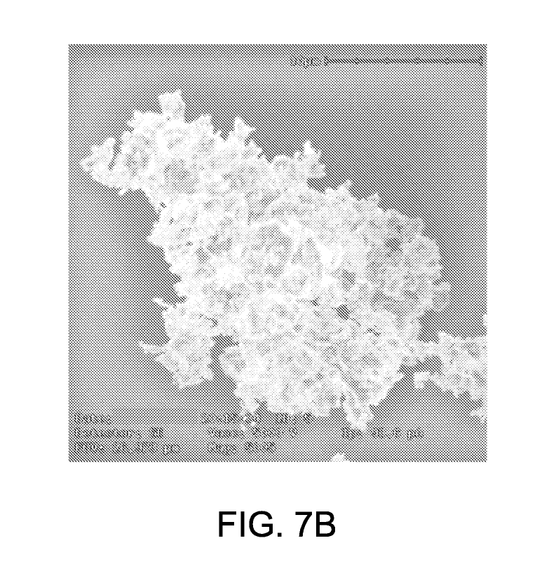

During filtration, if forces between particles are strongly repulsive as is desired in cutting and cleaning, it is difficult to form a bridge over a filter-media pore, as the particles will tend to slide past each other on the filter media. In this case, even when a thin cake is formed, the further deposition of particles into a thick cake is characterized by the closing up of pores and poor filtration rate. See FIG. 7A, which depicts a thick filter cake characterized by poor filtration and FIG. 8, which depicts a structure with good filtration. FIG. 7B is a scanning electron micrograph of an aggregate particle that, if deposited on the cake and retains its form without slumping, would contribute to good filtration. Poor filtration may result from poor attractive forces between particles and filtration may be further degraded due to lubrication from Si(OH)₄-polyoxy gels.

Because the swarf particles tend to be flakes, in a flow field under purely repulsive inter-particle forces, the tendency will be to collapse into a compact, quasi-nematic form. Thus, coolant chemistry ideally set of for cutting and cleaning will be characterized by high initial flow rates through a filter, but with the vast majority of solids passing through, followed by the eventual formation of a thin cake which immediately chokes, and leading to very low flow rate of fluid.

For coolant recovery, the desired property is high initial flow rate characterized with clear-low solids filtrate, followed by moderate sustained flow of clear filtrate. This can be achieved by creating attractive inter-particle forces prior to filtration. Under those conditions, particles which collide in solution stick to each other, cannot slide past each other, and thus aggregate in large composite particles called flocs. The floc particles may then be filtered at a relatively high rate. See again FIG. 8, which depicts flow through a cake of flocculated particles, which is faster than through a uniform cake of swarf particles. With sticky particles formed in solution, floc aggregates in a cake retain open channels.

In untreated coolant used for slicing, the filter cake is too tightly packed at pH 8.9-9.9. This is due to poor attractive forces, and maybe lubrication from Si(OH)₄-polyoxy gels and nanoparticles of silicon. A totally repulsive force law allows tightly organized packing during drainage (FIG. 7). A sticky force law allows larger, more stable pore channels between flocs (FIG. 8). Consider a flow channel to be a capillary, whose flow rate Q is described by Poiseuille's law, Q goes as ˜R⁴/η where R is the radius of the pore and η is the local viscosity. If the mean channel size is increased from R to 1.5R, flow rate increases by 5×. Although a filter cake may eventually plug, flocculating the silicon-containing swarf prior to filtration dramatically delays plugging of the filter and further enables high filtering rates by retaining open channels, even if the percentage change in channel size is small.

With no treatment of coolant, typical systems achieve on the order of ˜20-50 L/(m² hr). A recycling method according to the present invention enables filter rates on the order of 200 to 500 L/(m² hr), which is the flow rate dominated by the structure of the filter cake rather than the filter media. Filtering untreated coolant fluid over time builds up unfiltered nanoparticles which eventually cause the coolant fluid to become amber or even grey in color. The particle buildup eventually closes channels on the filter medium and slows down the filter rate. The coolant fluid recycling process is thus slow and imperfect, resulting in low wafer yield. Low fluid flow rates through the filter may be obviated by installation of large filter banks, but the costs associated with these results are not economical. Using the coolant and throwing it away, even if using is for a few filtration cycles, is uneconomical due to the cost of the polymer additive and the cost of making high quality water.

What is needed for filtration is a way to switch on attractive forces between particles, so that the flocs may form. These forces are those well understood in the field of colloid and interface science, as explained in standard texts and monographs [(Hunter 2001) (W. B. Russel 1992) (Arthur W. Adamson 1997) (Henk N. W. Lekkerkerker 2011)]. Typically, colloidal particles are treated as ideal spheres, for which standard models of interaction are well formulated. The silicon-containing swarf particles are not spheres, but are irregularly shaped flakes. Therefore model calculations of these forces are qualitative and not necessarily quantitative.

The present invention is therefore directed to a process for treating coolant fluid used in wire-saw cutting of semiconductor wafers. The process comprises contacting the coolant fluid with a flocculant polymer to thereby form aggregate particles comprising the silicon-containing swarf and the flocculant polymer; which is followed by filtering the coolant fluid comprising the aggregate particles to separate the aggregate particles from the coolant fluid to thereby yield a coolant fluid filtrate. The filtered coolant fluid advantageously is substantially devoid of silicon-containing impurities and additionally contains very little flocculant polymer and is suitable for reuse in a wire-saw cutting operation. Advantageously, the method of the present invention enables coolant fluid to be recycled through multiple wire-saw cutting operations with, at most, only minimal replenishment of additives during each operation.

According to the present invention, a flocculating agent is added to used coolant fluid during a coolant fluid recycling process. Preferably, the flocculating agent binds specifically to impurity particles, e.g., silicon-containing particles, such that the particles flocculate, and the flocculating agent is such that substantially all of the flocculating agent does not pass into the filtrate. Flocculating agents used in the method of the present invention advantageously possess the following properties: (1) reduced flocculant breakthrough in the return loop to the sawing process; (2) reduced impurity breakthrough; (3) operates at the undisturbed pH of the coolant fluid; (4) does not generate extra soluble silica—ideally scrubs soluble silica; (4) low toxicity; (5) low cost; (6) recovers quickly from overdosing; (7) does not interfere with the recovery of silicon from swarf; and (8) operates quickly, e.g., on the timescale of 10's of minutes or less. The pH of the coolant fluid containing silicon-containing swarf is at least about 7.0, such as at least about 8.0, such as at least about 8.9, such as between about 8.9 and about 10.0, such as about 9.5.

In some embodiments, the flocculant polymer comprises a cationic repeat unit since polymers comprising generally positively charged repeat units are capable of forming ionic bonds and/or hydrogen bonds with generally negatively charged silicon-containing particles. In some embodiments, the flocculant polymer comprises a cationic repeat unit comprising an amine. The amine may be a primary amine, a secondary amine, a tertiary amine, or a quaternary amine. Preferably, while in contact with the coolant fluid, the cationic polymers comprise a minimum positive charge per repeat unit of 0.5 positive charge/repeat unit, more preferably at least 0.8 positive charge/repeat unit, and even more preferably about 1.0 positive charge per repeat unit. High charge density as a function of molecular weight is still further preferred. For example, in some embodiments, the charge density per molecular weight is at least about 1 positive charge per about 300 Daltons, more preferably at least 1 positive charge per about 200 Daltons, and even more preferably at least about 1 positive charge per about 150 Daltons, such as at least about 140 Daltons, or even at least about 135 Daltons. Positively charged flocculant polymers include poly(N,N-diallyldimethylammonium), poly(N,N-diallyldimethylammonium HCl), polyacrylamide, polyethyleneimine, polyquaterniums, poly(allylamine), poly(allylamine HCl), polyimidazoles, polyvinylpyridines, alkylated polyvinylpyridines, poly(vinylbenzyltrimethylammonium), poly(acryloxyethyltrimethylammonium HCl), poly(methacryloxy(2-hydroxy)propyltrimethylammonium HCl), among others. Preferred flocculant polymers may be selected from among poly(N,N-diallyldimethylammonium), polyacrylamide, polyethyleneimine, and polyquaterniums.

In some embodiments, the flocculating agent comprises a polyacrylamide or a modified polyacrylamide. Polyacrylamide (PA) comprises a non-ionic polymer which can be modified to be a weak base. Non-derivatized polyacrylamide has the following structure:

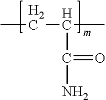

wherein m denotes the number of repeat units. In general, the value of m is such that the polyacrylamide has a molecular weight ranging from several thousands to several million Daltons.

The nitrogen atom on the polyacrylamide may be modified with cationic groups, e.g., amines, so that the material could bind specifically to silicate surfaces. A modified polyacrylamide may have the following general structure:

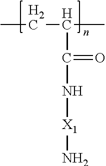

wherein X₁ comprises a connecting moiety; and n denotes the number of repeat units. In general, the value of n is such that the polyacrylamide has a molecular weight ranging from several thousands to several million Daltons. The connecting moiety may comprises an alkane, which may be substituted or un-substituted, and generally comprises from 1 to about 10 carbon atoms, preferably from 1 to about 6 carbons atoms, more preferably from 1 to about 4 carbon atoms.

In some embodiments, the modified polyacrylamide has the following specific structure:

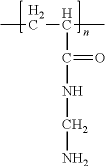

Specific suitable polyacrylamides for use as flocculants include Tramfloc® 302 available from TRAMFLOC, INC., Tempe, Ariz. Typical molecular weights are in the millions, and so the polymer is shear sensitive and difficult to disperse. Polymer which is not sold dry is pre-dispersed as an emulsion with mineral oil. The mineral oil dispersed in coolant is a hydrophobic material and may interfere with clean-ability of the wafers. Typically, the polymer is sensitive to bio-degradation, and so must be used shortly after dispersion. Acrylamide monomer may be present as an impurity and is toxic material. For 10's of ppm levels which would interfere with the clean-ability of wafers, there are no trivial analytical methods to detect mineral oil or residual polyacrylamide in the coolant fluid.

According to empirical results to date, when the flocculant polymer comprises polyacrylamide, the optimum dose of flocculant polymer is between about 0.001 grams of polyacrylamide per gram of silicon containing impurities and about 0.005 grams of polyacrylamide per gram of silicon containing impurities. More preferably, the optimum dose of flocculant polymer is about 0.0025 gm of polyacrylamide per gram of solids, with an error not exceeding +/−0.0005 gm/gm, preferably not exceeding +/−0.0003 gm/gm and most preferably not exceeding than 0.0003 gm/gm. The expected surface area of the solids, i.e., silicon containing impurities, is approximately 10 m²/gm. The optimum dose adjusted by the total surface area of particles in solution, that is to say the estimated optimum dose is 0.00025 gm polyacrylamide per m² of solids, and the polyacrylamide is added to a full tank and then aged no less than 20 minutes.

In some embodiments, the flocculating agent comprises a polymer comprising a quaternary amine. Polymers comprising a quaternary amine include poly(N,N-diallyldimethylammonium) and polyquaterniums. Polyquaterniums are commonly made by N-methylation with methyl chloride. For example:

R₁—NH—R₂+2CH₃Cl==>[R₁—N(CH₃)₂—R₂]⁺+Cl⁻+HCl

Depending on the density of charged sites per unit length, the efficiency of such a polymer as a flocculant in silicate based systems will be a function of pH. Although the charge density of a quaternary amine is substantially unaffected by pH changed, the charge density of silica is varies strongly as a function of pH. Accordingly, the dosing concentration is a function of particle quantity (surface area) and charge density of the particle. In low molecular weight forms, high charge density polymers can adsorb to surfaces, and locally reverse the sign of charge. At the optimum dose the overall surface charge is neutral, but contains patches of negative and positive charges. At close approach, the charges on opposing surfaces rearrange to attract each other by electrostatic double layer forces. See “Mathematical modeling of polymer-induced flocculation by charge neutralization” Venkataramana Runkana, P. Somasundaran, and P. C. Kapur, Journal of Colloid and Interface Science 270 (2004) 347-358 It is preferred that the charges be mobile, so therefore molecular weight should not be too high. Accordingly, in preferred embodiments, the molecular weight of the quaternium polymer may be between about 1000 to 100000 Daltons and preferably about between about 1000 and about 10000 Daltons. Additionally, preferably the polyquaternium polymer has a charge density per unit length of not less than about one per 15 Angstroms, preferably at least about one per 5 Angstroms, such as between about one per 5.9 Angstroms and about one per 12 Angstroms.

The polyquaternium flocculant to solids ratio does has a minimum value in order to achieve sufficient flocculation and removal of silicon containing impurity. Additionally, the concentration of the polyquaternium is preferably not high enough to re disperse the particles when total coverage is achieved with all positive charges. According to empirical results to date, the optimum dose of polyquat to achieve effective filtration is between about 5·10⁻⁵ 1:1 electrolyte molar equivalents of charge per gram of solids and about 20·10⁻⁵ 1:1 electrolyte molar equivalents of charge per gram of solids. In some preferred embodiments, the optimum dose of polyquat to achieve effective filtration is about 8.7·10⁻⁵ 1:1 electrolyte molar equivalents of charge per gram of solids, with an error less than 10%, preferably less than 5%, and most preferably less than 3%. The expected surface area of the solids, i.e., silicon containing impurities, is approximately 10 m²/gm. The optimum dose is adjusted by the total surface area of particles in solution, that is to say the estimated optimum dose is 8.7·10⁻⁵ 1:1 electrolyte molar equivalents of charge per m² of solids, and the Polyquat is added to a filling tank and then aged no less than 20 minutes once filling is complete.

In some embodiments, a high charge density flocculant polymer comprises poly(N,N-diallyldimethylammonium chloride) (poly(DADMAC)). The charging properties of poly(DADMAC) on silicate surfaces show that its optimum pH of the coolant fluid may range from about 7 to about 9, such as between about 8 and about 8.75, such as about 8.5 for effective use. See “Protonation of silica particles in the presence of a strong cationic polyelectrolyte,” D\check{u}sk\check{u} Cakara, Motoyoshi Kobayashi, Michal Skarba, Michal Borkovec, Colloids and Surfaces A: Physicochem. Eng. Aspects 339 (2009) 20-25.

In some embodiments, the coolant fluid pH is at least about pH≧8.9, such as between about 8.9 and about 10, such as about 9.5. In embodiments in which the coolant fluid pH is greater than about 8.9, a polymer of very high charge density is preferred. In these embodiments, the flocculant polymer comprises a polyquaternium having the general structure:

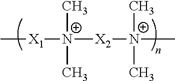

wherein X₁ and X₂ are connecting moieties and n denotes the number of repeat units. In general, the X₁ and X₂ are connecting moieties are low molecular weight alkanes, which may be substituted or un-substituted, having generally from 1 to 6 carbon atoms, preferably 2 to 4 carbon atoms, even more preferably 2 or 3 carbon atoms. The alkanes may comprise intervening heteroatoms, such as nitrogen, oxygen, and sulfur, preferably oxygen.

In some preferred embodiments, the flocculant polymer comprises polyoxetonium chloride (PQ42), (CAS number 31512-74-0; (Poly[oxyethylene(dimethyliminio)ethylene(dimethyliminio)ethylene dichloride]; Armoblen NPX; BL 2142; Bubond 60; Busan 1507; Busan 77; MBC 115; Polyoxetonium chloride; Polyquaternium 42, PQ42.). PQ42 has the following structure:

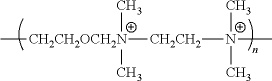

The molecular weight average is 3886 grams/mole, which corresponds to a degree of polymerization of ˜15. The molecular weight may range from between about 1000 to 10000, which corresponds to a degree of polymerization of 4-40.

PQ42 has relatively low molecular weight that is conducive to charge patch neutralization. The small molecule is mobile on the surface on swarf particles. An ab initio Hartree-Fock calculation of a segment of polyoxetonium, O(OH)₂SiOSi(OH)₂O, in a water cluster shows that this molecule has the right shape and size to dock with HOSi—O—Si—OH structures on the surfaces of particles; therefore, the preferred embodiment comprises X₂ as —CH₂CH₂— as in PQ42. Accordingly, it has the possibility of scrubbing the coolant of soluble silicates, which are precursors for colloidal silicate particles. Colloidal silica is just as undesirable for the cutting process as are particles of silicon. Soluble silica in swarf that is drying on wafers precipitates out as its concentration increases, acting as a cement between particles.

Polyquaterniums are commonly charged balanced with chloride. It has been observed that chloride ion concentration builds up over multiple filtration cycles. Additionally, use of polyquaterniums charged balanced with chloride may alter the pH of the coolant fluid. In some embodiments, an efficient coagulant is treated to remove corrosive anions from a flocculant by using successive cycles of bipolar electrodialysis replacing them with hydroxide ions, and replacement of excess hydroxide ions with benign anions of relatively low ionic mobility. Because of chloride anion, in a system that efficiently recovers coolant, chloride build up has several disadvantages. Aside from the increased rate of corrosion of wire-saw parts, any wire left exposed to coolant that dries (and concentrates chloride) is especially vulnerable to breakage. Worse, when a saw is running, the increased electrolytic conductivity interferes with the wire break detection systems of commercial wire-saws.

Additionally, polyquaterniums charged balanced with chloride result in a decrease in the pH of the coolant fluid due to ion exchange generating HCl. For example:

≡SiOH+PQ⁺Cl⁻>>≡SiO⁻PQ⁺+HCl.

PQ is particularly useful because, empirically, it can displace sodium ions from the particle surfaces to reverse or neutralize the surface charge. Sodium hydroxide is perhaps the cheapest method to restore pH and it does not interfere with PQ induced flocculation.

A potential side effect of using PQ42 in a coolant recovery system is the build-up of corrosive chloride ions. These ions will attack piping systems and saw components. Even at alkaline pH the chloride will attack the saw components made out of stainless steel. Coolant that is allowed to dry on used wire concentrates the chloride as it dries. The concentrating chloride solution may corrode and weaken the wires to the point that wire breakage is possible while the wire is idle and under tension.

Therefore, the process of the present invention further includes a step of pre-treating the polyquaternium to remove chloride ion before its addition to the system. A number of ways can be contemplated. In some embodiments, the polyquat charge balanced with chloride may be treated with a salt comprising a cation that precipitates chloride as an insoluble or sparingly soluble metal salt. Suitable elements for such purpose are mercury, lead, or silver. These are either toxic, expensive, or both.

In some embodiments, a solution comprising the polyquat may be ion exchanged in an ion exchange column. The column is filled with a resin that is preferentially binding to chloride ions. Typically such resins are themselves high molecular weight polymers containing quarternary amine functional groups, or weak base amine groups. The efficiency of chloride ion exchange tends to be low. Further, the column will have to be regenerated frequently and will have to be of a large size to handle the mass of chloride treated in an industrial application. The process will tend to dilute the PQ material, and variation will creep in as differing amounts of water will be required to push through the PQ material depending on the resin batch age and condition.

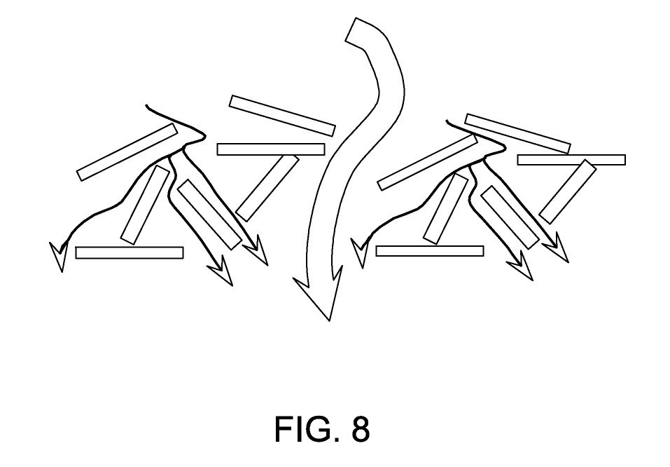

In some embodiments, the polyquat charge balanced with chloride ion is subjected to bipolar electrodialysis (BPED) to exchange chloride ions for hydroxide ions. The basic BPED process is shown in FIG. 9. The BPED system comprises cationic polymer that acts as an anion exchange resin, which blocks the permeation of cations therethrough. The BPED system comprises anionic polymer that acts as a cation exchange resin, which blocks permeation of anions therethrough. The bipolar membrane splits water, and separates chloride ion from the polyquat as HCl. The polyquat becomes charge balanced with hydroxide ion. Each membrane stack is a percentage remover, and multiple stacks are preferably used to quantitatively separate chloride ion from the polyquat. The process is improved when concentrated solutions are dialyzed due to higher electrical conductivity. Brine-water is the make-up fluid in otherwise unmarked channels. This is required to maintain electrical conductivity and have a place to dump unwanted ions. Most of the chloride, e.g., at least 50%, at least 60%, at least 70%, or even at least 80% of the chloride can be removed in just 2 to 6 passes. Without further treatment, the pH will rise as a result, but can be adjusted downward by adding a non-corroding acid, such as acetic acid. The chemistry of the BPED process for chloride removal becomes less efficient when the dominant anion becomes hydroxide. It is an object of the invention that addition of acetate or other ions to react with hydroxide and thereby produce water will improve the efficiency of chloride removal by BPED.

The efficiency of BPED for chloride removal declines as hydroxide ion concentration builds up in the system. The reason for this is due to hydroxide becoming the dominant charge carrier in electrolytic current flowing through the cationic resin membranes in the BPED stack. This happens when the number density of hydroxide ions exceeds that of chloride ions, and in addition, the equivalent conductivity of hydroxide is higher than chloride. See Table 1, which provides the equivalent ionic conductance at infinite dilution, ohm⁻¹ cm² at 25° C. (Reddy 1973), for several cations and anions.

TABLE 1

| Cation | λ⁺ₒ | Anion | λ⁻ₒ |
|---|---|---|---|
| H⁺ | 349.82 | OH⁻ | 198.5 |
| K⁺ | 73.52 | Cl⁻ | 76.34 |
| Na⁺ | 50.11 | Br⁻ | 78.4 |
| ½ Ba⁺⁺ | 63.64 | CH₃CO₂⁻ | 40.9 |

The mobility of the ions in the membrane is not known but the trend should be same, due to the sizes of the hydrated ions. After each or every other BPED pass, the pH may be reduced with, e.g., acetic acid, keeping the pH at or below 7. In doing so, hydroxide ion combines with the added protons to form water, and the charge carrier is acetate. As shown in the above table, acetate ion has less mobility than chloride. Therefore under BPED conditions, chloride will preferentially conduct current over acetate, and therefore chloride will be preferentially removed. Further removal of chloride from the polyquat may be accomplished by periodically adding a low ionic conducting anion, such as acetate, compared to normal BPED where chloride is exchange for hydroxide without pH adjustment. Furthermore, this method allows the end product pH to be adjusted to the desired coolant pH, so that we minimize the pH shift of coolant when adding PQ material.

Accordingly, the process of the present invention therefore may comprise a step wherein the flocculant polymer undergoes an anion exchange process with an anion having an equivalent ionic conductance at infinite dilution of less than about 77 ohm⁻¹cm⁻² at 25° C., or less than about 50 ohm⁻¹cm⁻² at 25° C. In some preferred embodiments, the anion is selected from the group consisting of acetate, propionate, butyrate, citrate, benzoate, succinate, picrate, tartrate, lactate, malonate, malate, and valerate. Acetic acid is preferred due to the low mobility of the ion, low cost, and very low toxicity.

BPED-PQ made with, e.g., acetate, will as a consequence also build up salts in the system. Instead of NaCl, however, the salt that builds up is the equivalent molar amount of sodium acetate, which in alkaline pH has solution conductivity roughly ˜30% lower at the same dilution. The result of using BPED-PQ with acetate exchanged for chloride will be fewer false signals of wire breakage in wire-saws that detect wire breakage by conductivity. Further, if the limit on concentration, controlled by conductivity is set by the bleed and feed rate for the coolant, the bleed and feed rate is reduced proportionally.

In some embodiments, the flocculant agent comprises a polyamine comprising non-quaternary amines, e.g., primary, secondary, and tertiary amines. Advantageously, such polymers may be prepared free of counterbalancing anions. Such polymers should bind to silicate surfaces and be capable of bridging two particles together. In some embodiments therefore, the flocculant agent comprises a polyethyleneimine. Polyethyleneimines may be linear or branched. In a preferred embodiment, the polyethyleneimine is branched. A branched polyethyleneimine may have the following random structure:

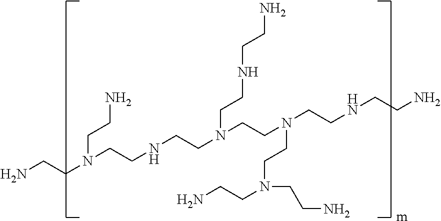

wherein m denotes the number of repeat units. The branched PEI may have a molecular weight ranging from about 1000 g/mol to about 5000 g/mol, such as between about 1500 g/mol and about 3000 g/mol.

The concentration of the PEI has a minimum value, e.g., mass of flocculant per surface area of silicon-containing swarf, in order to achieve sufficient flocculation and removal of silicon containing impurity. Additionally, the concentration of the PEI is preferably not high enough to re-disperse the particles when total coverage is achieved with all positive charges.

According to empirical results to date, the optimum dose of PEI to achieve effective filtration may be between about 1.0·10⁻⁵ mole of PEI monomer unit per gram of solids and about 1·10⁻³ mole of PEI monomer unit per gram of solids. In some embodiments, the optimum dose is 1.0·10⁻⁴ mole of PEI monomer unit per gram of solids, with an error not exceeding −10% to +300%, preferably not exceeding −5% to +20%, and most preferably not exceeding than −3% to +10%. The expected surface area of the solids, i.e., silicon containing impurities, is approximately 10 m²/gm. The optimum dose is adjusted by the total surface area of particles in solution, that is to say the estimated optimum dose is 1.0·10⁻⁵ mole of PEI monomer unit per m² of solids, and the PEI is added to a full tank and then aged no less than 20 minutes. Empirically, PEI can be used in the pH range 8.5-10, preferably in the range 8.9-9.5, and most preferably in the range 8.9-9.2.

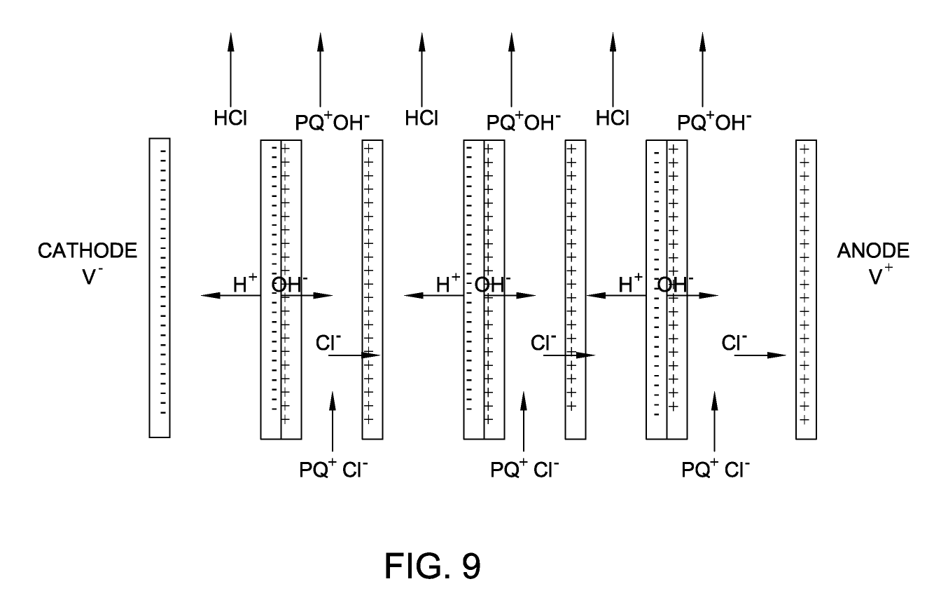

The unique properties of the organic flocculants, their tight and specific binding to particles with low breakthrough can be exploited in a novel way to recover and re-use coolant for wire-saw cutting. A basic schematic and procedural outline of such a system is shown in FIG. 10, but it is not exclusive to variation on the design. The procedural outline is:

(1) Prepare fresh Coolant

(2) Pump particle-free and flocculant-free coolant to wire-saw

(3) Cut wafers

(4) Pump the used coolant fluid to Collection tank(s)

(5) Add flocculant and age in the reaction-aging tank(s)

(6) Filter in the filter system

(7) Remove solids including swarf waste and remove liquid waste

(8) Add make-up volume of water and coolant polymer additives

(9) Return to step (2)

In some embodiments, the flocculant is added in step (5) with agitation. For example, the tank may comprise paddle mixers, rotary jet mixers, propeller mixers, impeller mixers, or magnetic mixers, among other techniques for providing agitation known in the art in order to provide agitation during addition of the flocculant to the used coolant fluid. The details in mixing and aging depend on the nature of the binding of the flocculent. For example, PQ tends to be relatively mobile and redistributes itself uniformly in a tank while stirring, while PEI tends relatively immobile and does not readily redistribute itself between dosed and un-dosed particles, and so PEI may either be added to full tanks with rapid mixing, or added continuously to coolant fluid flowing into the process tank.

In some embodiments, the coolant fluid is temperature controlled during flocculation and aging. More preferably, the coolant fluid is controlled during the entire process, e.g., at each point in a close loop coolant recovery system. Preferably, the coolant fluid is maintained at a temperature below the cloud point of the coolant, which may depend in substantial part on the additives used to make up the coolant fluid. Clouding occurs when a coolant polymer becomes less soluble with rising temperature. That is a characteristic of polymers which have polyethylene oxide chains mixed with relatively hydrophobic chains. An example of this class of polymer is a PLURONIC™; and MINFOAM™ type surfactants behave similarly. Clouded coolant gels with the swarf and makes it nearly impossible to filter.

In any kind of coolant recovery system, through error, the filter media can become fouled. Accordingly, the coolant recovery system is equipped with a filter washing capability. The filter can be of any type that allows separate recovery of solids and liquids, e.g., a candle filter with reverse flow capability, filter press, or other mechanism. A system of this type has demonstrated as much as 99% recovery of liquid per pass. This allows improved cost efficiency of coolant additives, and minimizes the volume of swarf that must be disposed or recovered and purified into solar or semiconductor grade silicon.

In coolant recovery circulatory systems which recover coolant as in FIG. 10, the flow of fluid in tanks with entrained air generates foam, because most coolant additives are surface active chemicals. This foam can be in such quantity as to overflow tanks and leave the system; and can cause significant loss of expensive polymer additive as a result.

Therefore, antifoaming agents can be added to prevent coolant loss to foam. Common agents are silicones, siloxanes and oils which have the unfortunate property of displacing water on as-cut wafer surfaces, binding particle to the wafer surface. In subsequent cleaning, etch masking of the surface can produce patterns matching those as shown in FIG. 6.

A suitable anti-foaming agent must be compatible with the coolant additives and not generate stains. In a search for suitable agents, some but not all based on alkynediols (comprising alkynediols, which are optionally modified with glycols, including ethylene glycol and propylene glycol) were found suitable and compatible with Pluronic type coolant additives. Suitable anti-foaming agents have the general structure:

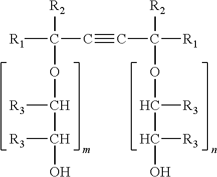

wherein R₁ and R₂ are independently hydrogen or alkyls having from one to twelve carbon atoms, such as from one to eight carbon atoms, such as from one to five carbon atoms, or from one to four carbon atoms; R³ is hydrogen or methyl; and m and n denote the number of repeat units. In some embodiments, the R¹ and R² may be hydrogen, methyl, ethyl, n-propyl, isopropyl, n-butyl, sec-butyl, isobutyl, tert-butyl, pentyl, neopentyl, isopentyl, hexyls, octyls, or decyls. In some embodiments, each R³ is hydrogen. In some embodiments, one R³ is hydrogen and one R³ is methyl in each polyglycol portion of the compound.

Suitable anti-foaming agents are Surfynol 440 (Air Products), Surfynol DF110D (Air Products), Surfynol 61 (Air Products) in doses from 500 to 1000 microliters per liter of coolant. Pluronic coolant additives are in common use for cutting fluids, and are based on block co-polymers of polyethylene oxide-polypropylene oxide.

According to the method of the present invention, the addition of flocculant polymer enables the removal of at least 90% of the silicon-containing impurities, preferably at least 95% of the silicon-containing impurities, at least 98% of the silicon-containing impurities, at least 99% of the silicon-containing impurities, at least 99.9% of the silicon-containing impurities, or even at least 99.99% of the silicon-containing impurities. Used coolant fluid containing silicon-containing swarf is generally opaque. Visibly amber, grey, or cloudy coolant invariably correlates to bad coolant performance in the sawing process. The method of the present invention enables recycling of used coolant fluid that returns the turbidity to no greater than about 20 nephelometric turbidity units (EPA method 180.1), preferably less than 10 NTU, and most preferably less than 5 NTU contribution from solids.

In some alternative embodiments of the process of the present invention, the pH of used coolant is reduced to a value low enough to cause precipitation of silicon-containing impurity particles. This embodiment of the present invention is based on the observation that silicon-containing impurities, e.g., silicates, precipitate are reduced pH. The precipitated particles may then be filtered. After filtration the pH can be raised again to be >8.5, preferably 9.5 prior to use in a wire-saw cutting operation. The use of acidifying agents to lower the pH may disadvantageously increase the ionic system of the recycled coolant fluid. Eventually the ionic strength of the coolant fluid may be so high that repulsive electrostatic forces can no longer repel particles from each other. The result is (1) dirtier wafers (2) solids build up on wire guides and saw components (3) a build-up of small particles in the re-circulating coolant (5) false wire-break signals due to increased conductivity of the coolant. Accordingly, utilization of these embodiments of the present invention comprises an additional step to lower the ionic strength of the coolant fluid prior to use in a wire-saw cutting operation.

In some embodiments of the process of the present invention, used wire-saw coolant fluid may be first treated with an acid to lower the pH of the coolant fluid to thereby cause precipitation of silicon-containing impurities. The solids containing the silicon containing impurities are then filtered. The filtrate is then treated with a base, which contains a cation that precipitates the anion contributed by the acid. Again, the coolant fluid may be filtered to remove the precipitate. The coolant fluid which has been treated to remove silicon-containing impurities may then be used in a wire-saw cutting operation. Acid-base combinations that result in insoluble salts can be found in the literature (Lide 1993-1994) and as set forth in the following tables 2 and 3. Suitable acids for lowering the pH include sulfuric acid, oxalic acid, carbonic acid, tartaric acid, and phosphoric acid. Suitable bases for returning the pH of the coolant fluid to a pH appropriate for wire-saw cutting include magnesium hydroxide, barium hydroxide, zinc hydroxide, calcium hydroxide, and manganese(II) hydroxide. According to these embodiments of the present invention, the concentration of the silicon-containing impurities in the coolant fluid filtrate is reduced by at least about 85%, at least about 90%, or at least about 95% compared to the concentration of the silicon-containing swarf in the used coolant fluid prior to contact with the acid. Stated another way, the concentration of the silicon-containing impurities in the coolant fluid filtrate is less than about 1000 ppm silicon equivalent, or less than about 500 ppm silicon equivalent.

Table 2 of solubilities of selected acid-base combinations.

| | | | gm/ | Solubility |
|---|---|---|---|---|
| Substance | Formula | ° C. | mole | (moles/liter) |
| Barium sulfate | BaSO₄ | 25 | 233.43 | 1.05E−06 |
| Zinc oxalate | ZnC₂O₄•2H₂O | 18 | 189.43 | 4.17E−06 |
| Calcium oxalate | CaC₂O₄ | 13 | 128.10 | 5.23E−06 |
| Zinc carbonate | ZnCO₃ | 15 | 125.39 | 7.98E−06 |
| Barium carbonate | BaCO₃ | 20 | 197.34 | 1.01E−05 |
| Calcium carbonate | CaCO₃-Calcite | 25 | 100.09 | 1.40E−05 |
| (Calcite) | | | | |
| Calcium carbonate | CaCO₃-Aragonite | 25 | 100.09 | 1.53E−05 |
| (Aragonite) | | | | |
| Calcium tartrate | CaC₄H4O₆•4H₂O | 35 | 260.21 | 3.00E−05 |
| Barium oxalate | BaC₂O₄•2H₂O | 18 | 225.35 | 4.13E−05 |
| Manganese(II) | MnCO₃ | 25 | 114.95 | 5.65E−05 |
| carbonate | | | | |
| Barium tartrate | BaC₄H₄O₆•H₂O | 18 | 303.42 | 8.57E−05 |
| Barium hydrogen | BaHPO₄ | 20 | 233.31 | 8.57E−05 |
| phosphate | | | | |
| Magnesium carbonate | MgCO₃ | 20 | 84.31 | 1.26E−04 |
| Magnesium oxalate | MgC₂O₄•2H₂O | 16 | 148.36 | 4.72E−04 |
| Calcium sulfate | CaSO₄ | 30 | 136.4 | 1.53E−03 |
| Calcium | Ca(H₂PO₄)2•H₂O | 30 | 252.07 | 7.14E−03 |
| Orthophosphate | | | | |
| Magnesium phosphate | Mg₃(PO₄)₂ | 20 | 262.86 | i |

Table 3 of Solubilities of selected silicates

| | | | gm/ | Solubility |
|---|---|---|---|---|
| Substance | Formula | ° C. | mole | (moles/liter) |
| Magnesium metasilicate | MgSiO₃ | 20 | 100.39 | i |
| Calcium metasilicate | CaSiO₃ | 17 | 116.16 | 8.18E−05 |
| Barium metasilicate | BaSiO₃•6H₂O | 20 | 321.51 | 5.29E−04 |

In an exemplary embodiment and with reference to the above table 2 of solubility of selected acid-base combinations, used coolant fluid may be recycled by adding an acid such as oxalic acid to thereby lower the pH of the coolant fluid to about 7 or lower to thereby precipitate silicon-containing impurity particles. According to the method of the present invention, the coolant fluid with precipitated impurity particles may thereafter be filtered. The coolant fluid filtrate may then be contacted with a hydroxide base comprising a cation selected from among Zinc, Calcium, Barium, or Magnesium to thereby raise the pH to the appropriate pH for wire-saw cutting. The addition of the base comprising zinc ions, calcium ions, barium ions, or magnesium ions precipitates oxalate salts thereof, which may be filtered from the coolant fluid. Precipitation of the oxalate salts in turn prevents the build-up of ionic strength of the coolant fluid, which is ideal for avoiding false wire breakage signals during the wire-saw cutting operation. In another example, the coolant fluid may be contacted with bubbled CO₂ into the water to form carbonic acid, which can then be precipitated as a carbonate by calcium, zinc, barium, manganese, or magnesium.

The choice of reagents for pH can be chosen on the basis of cost, availability, and details of the apparatus required to add the reagents, as suits the user of the invention. A typical implementation would be to acidify to pH 7+/−0.5, age >20 minutes, then filter the swarf particles. The filtrate is then treated with the base to restore target pH, causing a precipitation of salt particles. These salt particles are easy to remove in subsequent cleaning process even though they have low solubility; by the correct choice of acid or other additive. In some cases, simple rinsing with de-ionized water is enough.

In each case there is an optimal pH for silicate scrubbing, depending on the cation, as is well known in the water treatment industry. It is possible to swing the pH back and forth with inexpensive reagents as noted above, where barium is the expensive outlier. Precipitation of soluble silica in the coolant before cutting sequesters soluble silica from reactions that bind particles together. Advantageously, the coolant fluid does not undergo significant changes in solution refractive index, or cloud point as a result of the cyclic treatment and swing of pH. Additionally, the polymer surfactant in the coolant remaining unaffected.

According to the method of the present invention, the use of pH toggling enables the removal of at least 85% of the silicon-containing impurities, preferably at least 90% of the silicon-containing impurities, at least 95% of the silicon-containing impurities, at least 98%.

The invention may be further illustrated by the following, non-limiting Examples.

### Example 1

### Polyacrylamide as a Flocculant

Tramfloc 302 was dispersed to manufacturer's instructions and used as a flocculant material for treating a full tank of used coolant fluid at a dose of 0.0025 gm/gm of solids. Tramfloc is added only with a full tank of coolant, and aged at least 30 minutes.

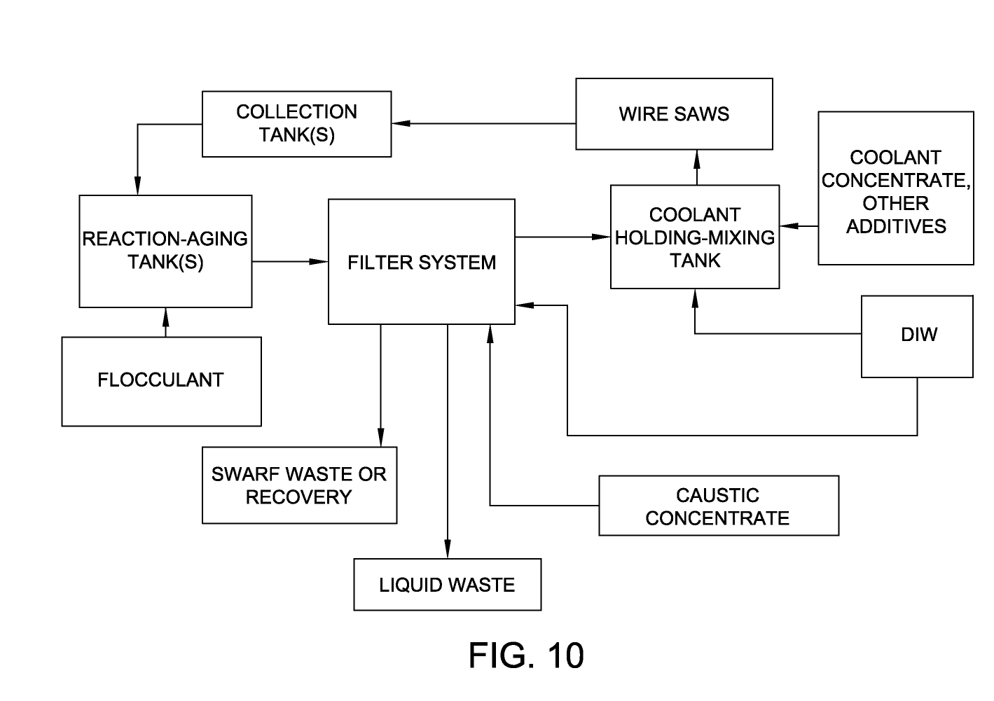

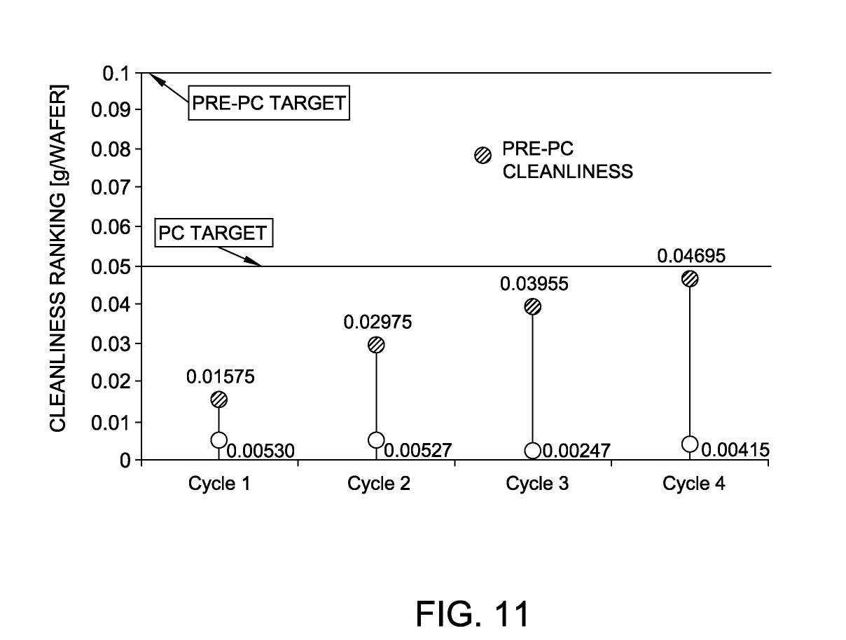

FIG. 11 provides cleanliness data for wafers cut using coolant fluid recycled using polyacrylamide flocculant. Successive applications of PA appeared to monotonically increase the dirtiness of as-cut wafers. Polyacrylamide evaluated as Tramfloc 302, was none-the-less effective at achieving acceptable flow rates as shown in FIG. 12.

The use of cationic polyacrylamide was effective to reduce silicon and silicates (measured as total silicon) to below 100 ppm (measured values in three samples (98, 95, and 90 ppm) in the filtered coolant.

### Example 2

### Polyquaternium as a Flocculant

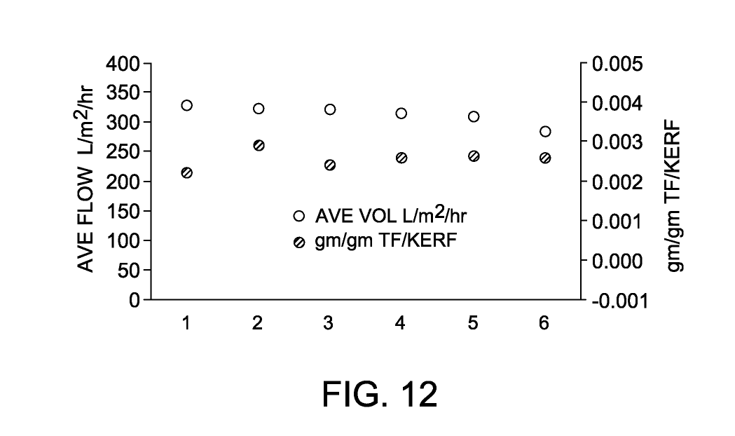

PQ42 was used as a flocculant material for treating used coolant fluid. The material was dosed at pH 9.5 with 8.68·10⁻⁵ 1:1 electrolyte equivalents per gram of solids and aged at least 30 minutes. FIG. 13 demonstrates that the use of PQ42, provided the mass ratio is kept close to the optimum, resulted in excellent filtration flow rate.

It was additionally demonstrated that the use of PQ42 in treatment of coolant effectively removed colloidal silicates from the coolant fluid and thereby prevented such silicates from being bound to the wafer during cutting, allowing a cleaner wafer immediately after sawing and reducing the effort required to make a clean final wafer. The resulting cleanliness is shown in the following Table 4 and expressed as grams of swarf solids per m² of wafer. Table 4 provides the average (n=17 samples) sawed wafer cleanliness and cleanliness after initial cleaning using coolant rejuvenated and recycled by PQ treatment for filtration.

TABLE 4
Sawed wafer cleanliness and cleanliness after initial cleaning.

| parameter | gm/m² as sawn | gm/m² simple clean |
|---|---|---|
| average | 1.24 | 0.68 |
| sigma | 0.95 | 0.63 |
| max | 3.96 | 2.20 |
| average + 3 sigma | 4.08 | 2.58 |

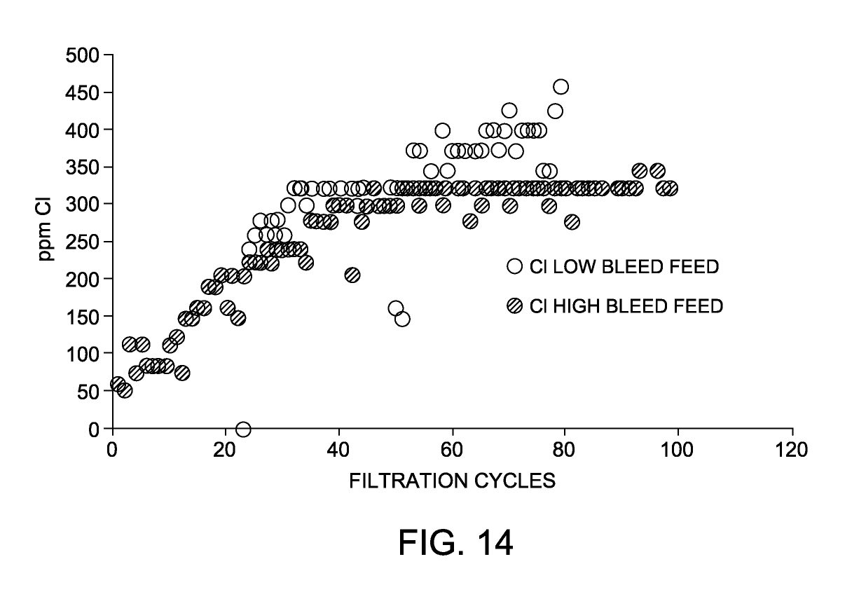

See FIG. 15, which provides the concentration of silicon-containing impurities through nearly 200 cleaning cycles of used coolant fluid. The quality of filtered coolant, as a function of its total solids, silicon and silicate as well as the level of soluble silica in total, was excellent through the multiple cycles. With PQ42 addition and the pH control by addition of NaOH to pH 9.5, the total silicon in the filtrate was kept under control.

### Example 3

### Bipolar Electrodialysis of Polyquaternium Flocculant

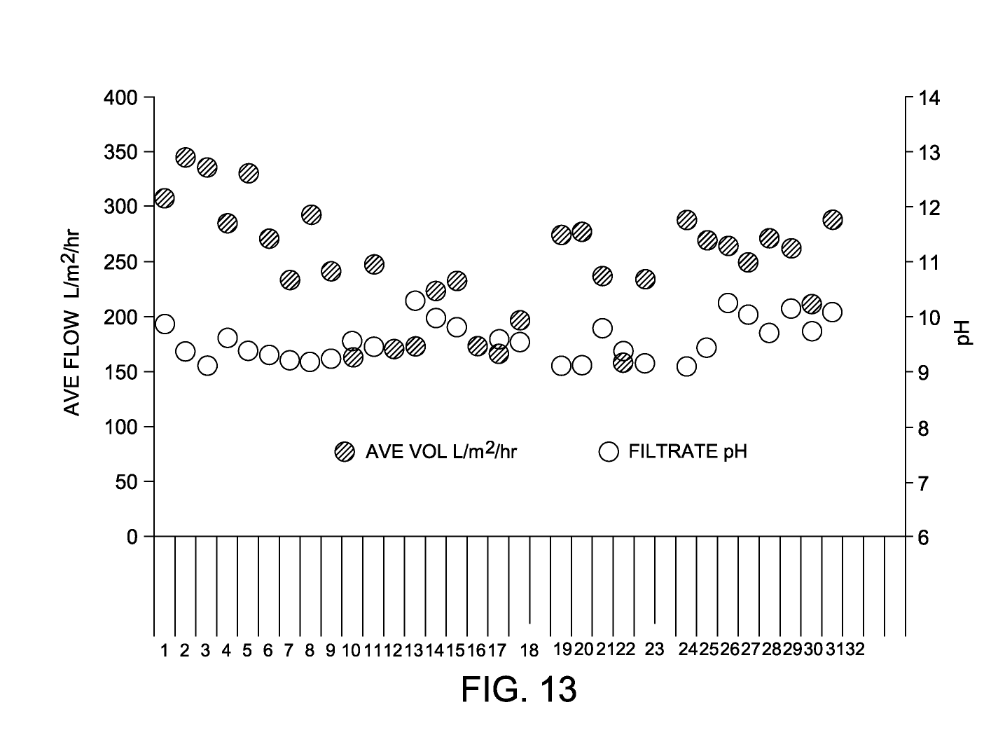

As shown in FIG. 14, the use of PQ42 eventually resulted in a buildup of chloride in the recycled coolant fluid. Accordingly, bipolar electrodialysis was used to treat PQ42 and to thereby replace chloride ion with an anion of less mobility. In these experiments, the replacement anion was acetate. Accordingly, PQ42 was subjected to bipolar electrodialysis such that chloride ions are replaced by acetate ions. BPED-treated PQ42 was used to treat coolant fluid in jar tests and scaled down coolant recovery system at pH 9.5, with flocculation and filtration performance indistinguishable from normal PQ42 with chloride.

### Example 4

### Branched PEI as Flocculant

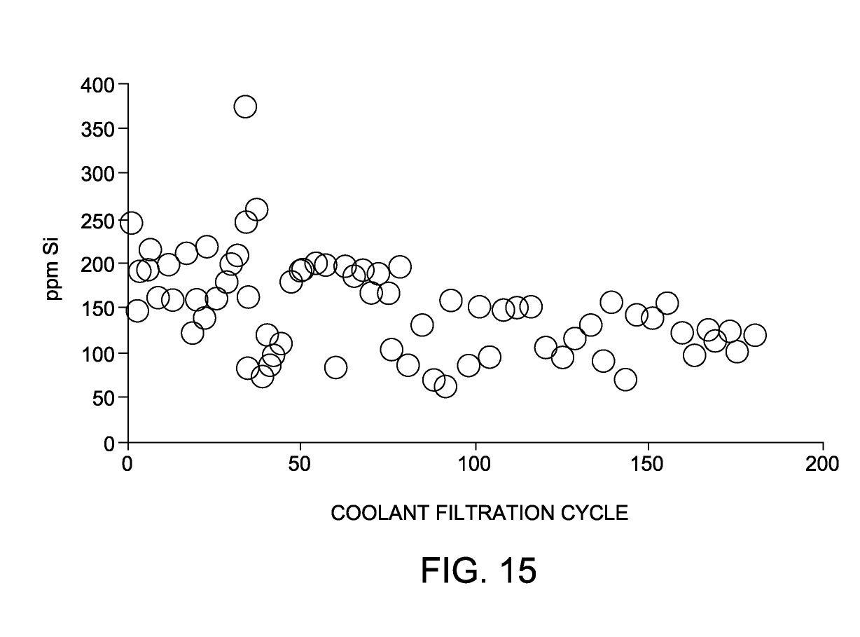

Branched PEI was obtained from Sigma-Aldrich, with given specifications: M_{w}˜2000 by LS, average Mₙ˜1800 by GPC, 50% wt. in H₂O, no chloride. Branched PEI was used as a flocculant material for treating used coolant fluid. As shown in FIG. 16, the use of PEI caused a slight shift in pH. The material was dosed at pH 9.5 with 4.5 ppm PEI per liter for every gm/liter of solids. Subsequent testing shows the optimum pH for using PEI to be 8.9-9.2, with coolant filtration performance equivalent to PQ42 in an operating factory, for at least more than 100 filtration cycles. For use of PEI, care was taken to only add to full coolant tanks with rapid stirring, and aging at least 30 minutes before filtration.

The following table 5 demonstrates the removal of silicon-containing impurities from used coolant fluid. Table 5 provides the average wafer cleanliness (n=22 samples) as sawn and after cleaning of wafers cut from coolant fluid recycled by PEI treatment for filtration.

TABLE 5
Sawed wafer cleanliness and cleanliness after initial cleaning.

| parameter | gm/m² as sawn | gm/m² simple clean |
|---|---|---|
| average | 1.29 | 0.31 |
| sigma | 0.49 | 0.17 |
| max | 2.32 | 0.78 |
| average + 3 sigma | 2.77 | 0.81 |

The level of cleanliness, demonstrated in Table 5, is comparable PQ42 (Table 4). In both case, the wafer cleanliness was such that a stack of sawed wafers can be singulated by an automated process.

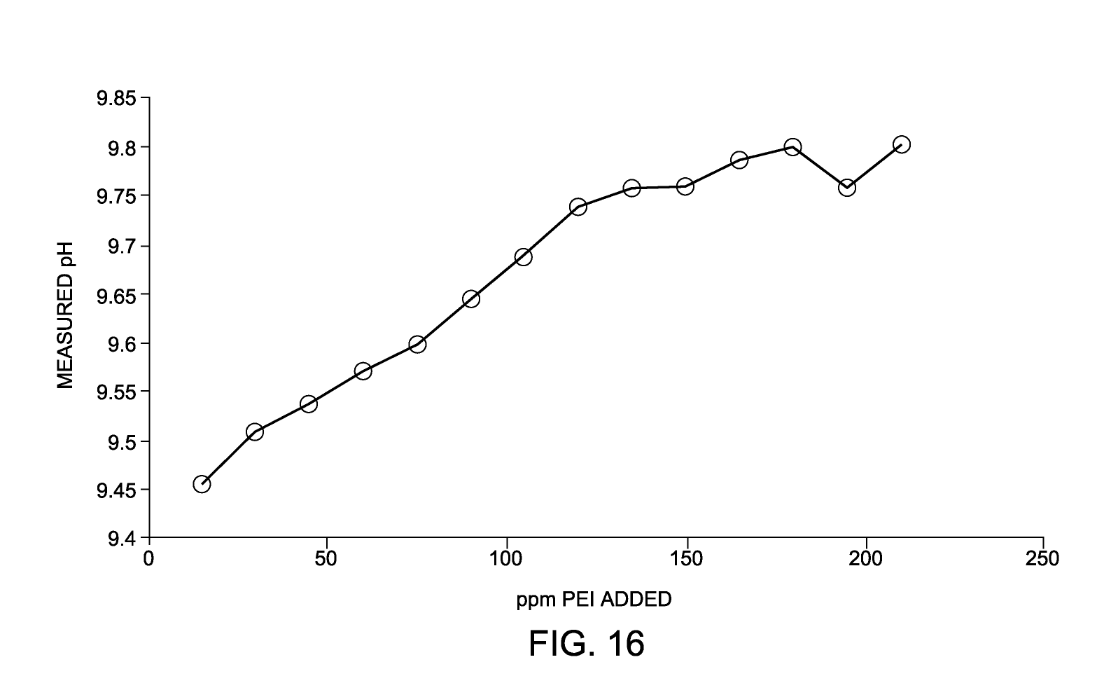

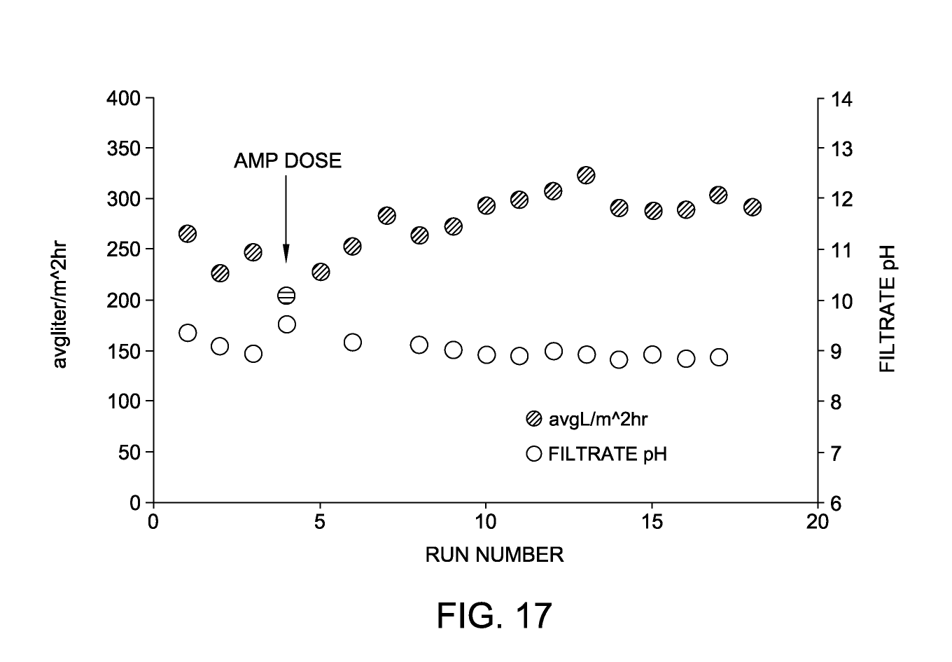

The average filtration flow rate is comparable to coolant treated with PQ. See FIGS. 17 and 18. In the PEI trial, on one occasion, the coolant pH was raised using a weak base, 2-Amino-2-methyl-1-propanol (AMP). In this case, the filtrate was amber instead of clear, and the filtration rate was depressed. These data demonstrate that amine polymers provided effective cleaning, rather than low molecular weight, non-polymeric amines. The dose of PEI to solids was relatively low, but not so low as to prevent filtration. Even under dosing with PEI did not create the amber coolant problem associated with the AMP dose. As AMP is a weak primary base, it appears that AMP competes with PEI for surface binding sites. AMP is not a polymer, can only bind to a single site, and therefore cannot bridge particles. Fortunately, PEI is itself a pH buffer, and continued use allows the pH to stabilize at a level which is safe for cutting. Even though the PEI stabilizes the pH, very little break-through of the polymer is detected. It is below the level required to induce flocculation with typical solids loading.

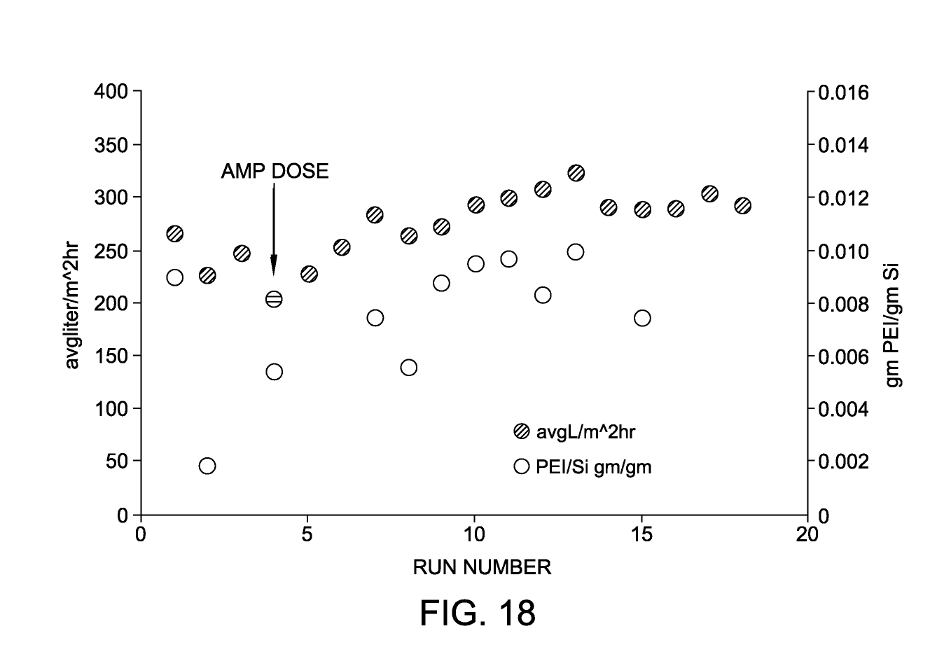

As shown in the Table 6, the amount of PEI break-though in recycled coolant in an operating system, is about ˜0.5% to ˜0.75% of the value required for flocculation. The minimum amount required to flocculate particles is approximately 40 ppm for a solids loading of 9.5 gm/liter. Such a low level of breakthrough does not impair performance of the saw. The coolant performed like new. See FIG. 19.

TABLE 6
PEI break-through in filtered coolant.

| Sample | PEI ppm in recycled coolant |
|---|---|
| Cycle | 0.33 ppm blank subtracted. |
| 1 | 0.19 |
| 2 | 0.19 |
| 3 | 0.15 |
| 5 | 0.29 |
| 6 | 0.29 |
| 7 | 0.29 |

### Example 6

### Nephelometry

A. Swarf fluid at 11 gm/liter of solids was collected and treated with PQ42 at 55 mg PQ42/liter of fluid. The material was aged 50 minutes in a feed tank prior to filtration. The average normalized flow rate was 5.10 liters m⁻² min⁻¹·bar⁻¹, in a system that can tolerate 2 bar pressure, and thus a maximum average flow rate of 10.2 liters m⁻² min⁻¹·bar⁻¹. Flow rate is normalized by pressure drop and filter area.

B. Swarf fluid at 10.6 gm/liter of solids was collected and treated with PEI at 84 mg PEI/liter of fluid. The material was aged 49 minutes in a feed tank prior to filtration. The average normalized flow rate was 4.84 liters m⁻² min⁻¹·bar⁻¹, in a system that can tolerate 2 bar pressure, and thus a maximum average flow rate of 9.7 liters m⁻² min⁻¹·bar⁻¹. Flow rate is normalized by pressure drop and filter area.

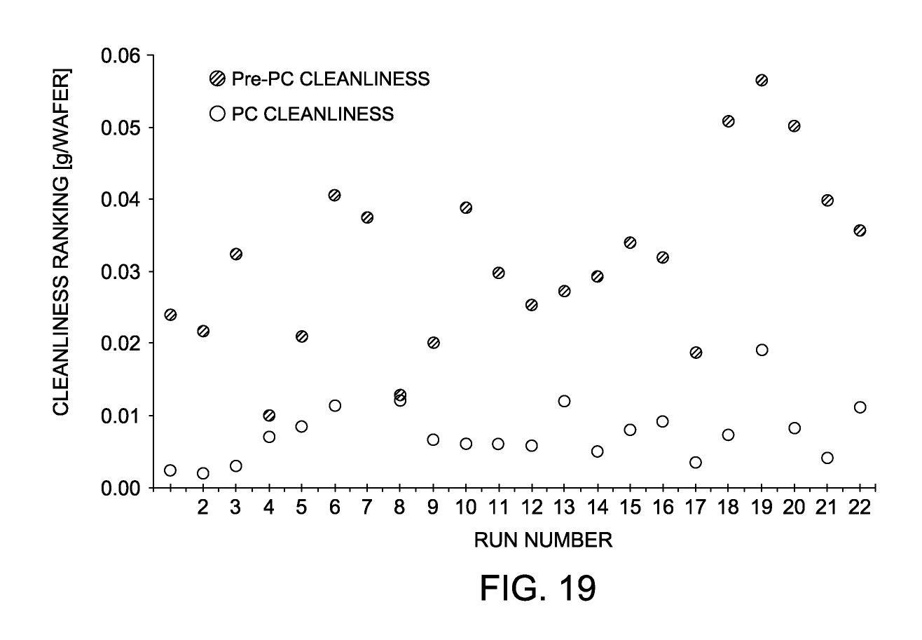

In both cases the fluid produced is substantially free of solid particles. Based on a measurement of turbidity, the solids content of filtered coolant is 0.097 ppm, and that translates to a solids removal efficiency of 99.99224% for the sample. The recovered coolant was crystal clear. A quantitative measure of-turbidity is by nephelometry (diffuse scatter of white light), and the process coolant measured 3.51 N.T.U. (nephelometric turbidity units). See FIG. 20, which is a calibration curve useful for comparing turbidity at measured by N.T.U. v.s. concentration of silicon-containing swarf. Pure water measures <0.1 NTU, and the naked eye can just start to detect turbidity at 10 to 20 NTU. Filtered coolant filtered through an absolute filter at 20 nm, has turbidity of 0.675 N.T.U., and this is intrinsic to the coolant polymer molecules. To use the curve, each measurement should be subtracted 0.675 NTU for the coolant, a small number for the vial itself (the 0.675 in my case includes the vial), and convert:

{(3.51−0.675)NTU/29.22=0.097 ppm solids}.

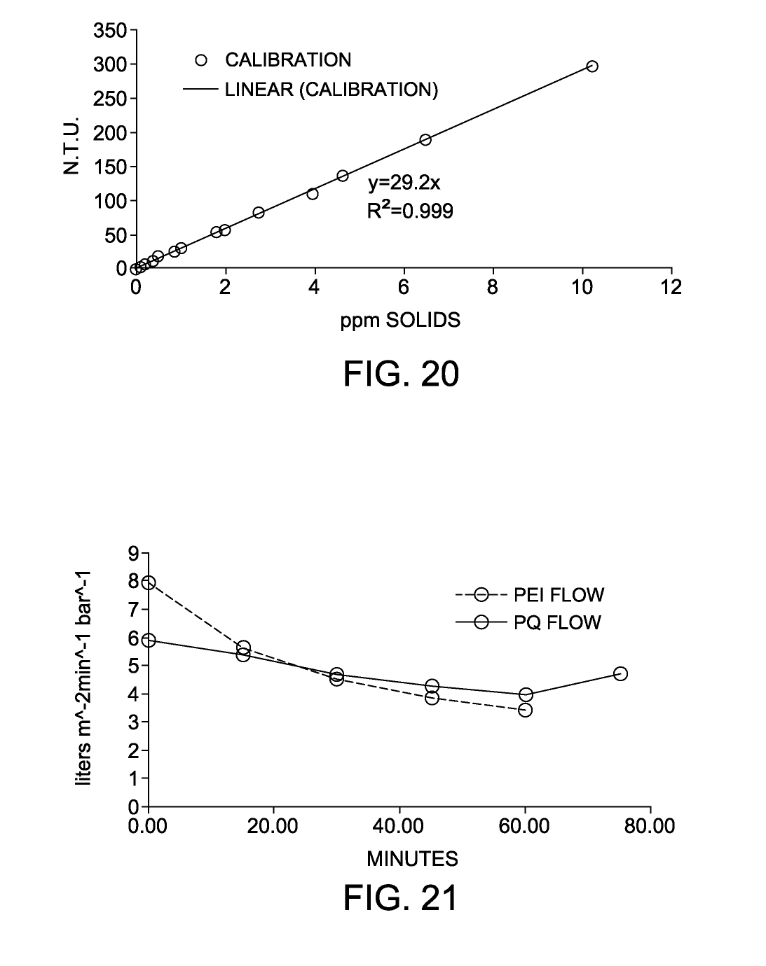

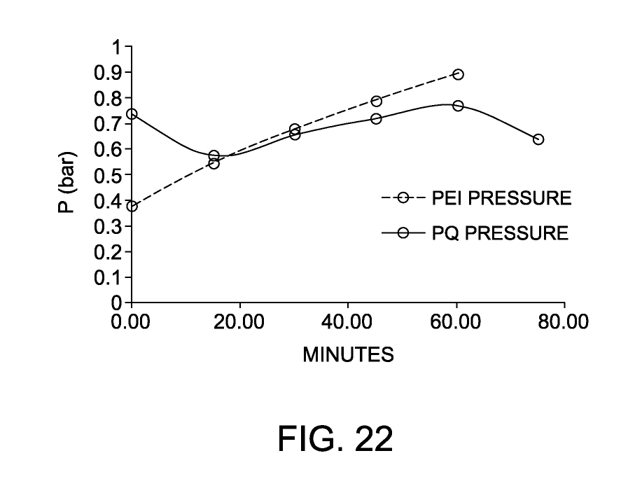

Normal swarf liquid at 1 to 20 gm per liter solids is opaque and therefore does not have meaningful turbidity associated with it. The above-treated solutions were clear. See also FIGS. 21 and 22, which are graphs depicting flow and pressure vs. time Data for examples 6A and 6B. FIG. 21 depicts instantaneous flow during swarf fluid filtration using comparably aged PEI and PQ flocculants (corrected). FIG. 22 depicts instantaneous pressure during swarf fluid filtration using comparably aged PEI and PQ flocculants. Note that for the bulk the filtration time, the pressure drop in both cases is the same. The system can sustain 2 bar pressure across the filter.

### Example 7

### Precipitation of Silicates Via pH Swing

Experiments were performed to show that this is possible to do in the presence of coolant chemistry which, might interfere in some way.

TABLE 7
Case 1 Ca(OH)₂, 1M and CO₂(g); 30 mL commercial coolant + 1 L water

| | Initial | | | | | Swing 3 + | |
|---|---|---|---|---|---|---|---|
| | Coolant | Swing 1 + 3% | | Swing 2 + 3% | | 3% Bleed/ | |
| Measurement | State | Bleed/Feed | | Bleed/Feed | | Feed | |
| pH, | 9.87 | 6.82 | 9.5 | 6.67 | 9.5 | 6.86 | 9.51 |
| log₁₀ ([H⁺]) | | | | | | | |
| Conductvity, | 1181 | 1129 | 1117 | 1188 | 1130 | 1213 | 1179 |
| μs | | | | | | | |

TABLE 8
Case 2 Mg(OH)₂, 1M and CO₂(g); 30 mL commercial coolant + 1 L water

| | Initial | | | | | | |
|---|---|---|---|---|---|---|---|
| | Coolant | Swing 1 + 3% | | Swing 2 + 3% | | Swing 3 + 3% | |
| Measurement | State | Bleed/Feed | | Bleed/Feed | | Bleed/Feed | |
| pH, log₁₀ ([H⁺]) | 9.78 | 6.95 | 9.57 | 7.34 | 9.49 | 8.09 | 9.34 |
| Conductvity, μs | 1191 | 1138 | 1399 | 1543 | 1719 | 2027 | 2077 |

TABLE 9
Case 3 Ca(OH)₂, 1M and H₃PO₄ 1N
30 mL commercial coolant + 1 L water

| | Initial | Swing 1 + 3% | | Swing 2 + 3% | |
|---|---|---|---|---|---|
| Measurement | Coolant State | Bleed/Feed | | Bleed/Feed | |
| pH, log₁₀([H⁺]) | 9.65 | 7.25 | 9.44 | 7.13 | 9.34 |
| Conductvity, μs | 1215 | 1138 | 1126 | 1105 | 1068 |

TABLE 10
Case 4 Mg(OH)₂, 1M and H₃PO₄, 1N 30 mL commercial coolant + 1 L water.

| | Initial | | | | | | |
|---|---|---|---|---|---|---|---|
| | Coolant | Swing 1 + 0% | | Swing 2 + 0% | | Swing 3 + 0% | |
| Measure | State | Bleed/Feed | | Bleed/Feed | | Bleed/Feed | |
| pH, log₁₀ ([H⁺]) | 9.72 | 7.15 | 9.13 | 7.14 | 9.15 | 7.03 | 9.41 |
| Conductvity, μs | 1174 | 1121 | 1251 | 1243 | 1337 | 1333 | 1496 |

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

1.-5. (canceled)

6. An as-cut silicon wafer having a central axis, a front surface and a back surface that are generally perpendicular to the central axis, a central plane in a bulk region of the structure between and parallel to the front and back surfaces, a circumferential edge, wherein the front surface, the back surface or both the front surface and the back surface of the as-cut silicon wafer has less than 2·10⁻⁴ gm/cm² silicon-containing impurities, the concentration of silicon-containing impurities is invariant with respect to the age of the coolant fluid used in the cutting operation, and the coolant fluid has been recycled from at least one prior wire-saw cutting operation.

7. The as-cut silicon wafer of claim 6 wherein the front surface, the back surface or both the front surface and the back surface of the as-cut silicon wafer have no defects which develop visible etch-masking during a subsequent cleaning process.

8. A population of as-cut silicon wafers, each wafer within the population having a central axis, a front surface and a back surface that are generally perpendicular to the central axis, a central plane in a bulk region of the structure between and parallel to the front and back surfaces, a circumferential edge, wherein the front surfaces, the back surfaces or both the front surfaces and the back surfaces of the population of as-cut silicon wafers has an average silicon-containing impurity concentration of less than 2·10⁻⁴ gm/cm² silicon-containing impurities, the concentration of silicon-containing impurities is invariant with respect to the age of the coolant fluid used in the cutting operation, and the coolant fluid has been recycled from at least one prior wire-saw cutting operation.

9. The population of as-cut silicon wafers of claim 8 wherein the front surface, the back surface or both the front surface and the back surface of the as-cut silicon wafer have no defects which develop visible etch-masking during a subsequent cleaning process.

10. The population of as-cut silicon wafers of claim 8 wherein the maximum silicon-containing impurity concentration is less than 4·10⁻⁴ gm/cm² silicon-containing impurities.

11. The population of as-cut silicon wafers of claim 8 wherein the maximum silicon-containing impurity concentration is less than 3·10⁻⁴ gm/cm² silicon-containing impurities.

12. A population of as-sawn silicon wafers, each wafer within the population having a central axis, a front surface and a back surface that are generally perpendicular to the central axis, a central plane in a bulk region of the structure between and parallel to the front and back surfaces, a circumferential edge, wherein, prior to any cleaning operation, the front surfaces, the back surfaces or both the front surfaces and the back surfaces of the population of as-cut silicon wafers has an average silicon-containing impurity concentration of less than 2·10⁻⁴ gm/cm² silicon-containing impurities, the concentration of silicon-containing impurities is invariant with respect to the age of the coolant fluid used in the cutting operation, and the coolant fluid has been recycled from at least one prior wire-saw cutting operation.

13. The population of as-sawn silicon wafers of claim 12 wherein the front surface, the back surface or both the front surface and the back surface of the as-cut silicon wafer have no defects which develop visible etch-masking during a subsequent cleaning process.

14. The population of as-sawn silicon wafers of claim 12 wherein the maximum silicon-containing impurity concentration is less than 4·10⁻⁴ gm/cm² silicon-containing impurities.

15. The population of as-sawn silicon wafers of claim 12 wherein the maximum silicon-containing impurity concentration is less than 3·10⁻⁴ gm/cm² silicon-containing impurities.
